(19) United States
(12) Patent Application Publication
(10) Pub. No.: US 2026/0259251 A1
(43) Pub. Date: Sep. 3, 2026

(54) ACTIVE POWER METERING DEVICE, ADJUSTMENT POWER METERING DEVICE, METERING METHOD, AND PROGRAM

(71) Applicant: MITSUBISHI HEAVY INDUSTRIES, LTD., Tokyo (JP)

(72) Inventors: Takaharu Hiroe, Tokyo (JP); Kazunari Ide, Tokyo (JP); Ryo Sase, Tokyo (JP)

(73) Assignee: MITSUBISHI HEAVY INDUSTRIES, LTD., Tokyo (JP)

(21) Appl. No.: 18/863,029

(22) PCT Filed: Feb. 17, 2023
(86) PCT No.: PCT/JP2023/005842

§ 371 Date: Nov. 5, 2024

(30) Foreign Application Priority Data
May 9, 2022 (JP) 2022-076918

(51) Int. Cl. G01R 22/06; G01R 23/02; H02J 13/12

(52) U.S. Cl. CPC G01R 22/061; G01R 23/02; H02J 13/12

(57) ABSTRACT

An active power metering device includes: a frequency estimator configure to estimate a cycle and a frequency of an alternating current based on a time series of a voltage of the alternating current transmitted to or received from a power system by a target device; and an active power meter configured to calculate a moving average value of instantaneous power in a plurality of cycles of the alternating current for each cycle of the alternating current, and meter active power exchanged by the target device in a cycle of the alternating current from a difference between the calculated moving average value and a previously calculated moving average value.

### TECHNICAL FIELD

The present disclosure relates to an active power metering device, an adjustment power metering device, a metering method, and a program used for adjustment of supply and demand of a power system and settlement of an electricity rate.

Priority is claimed on Japanese Patent Application No. 2022-076918, filed May 9, 2022, the content of which is incorporated herein by reference.

### BACKGROUND ART

A typical power meter conventionally used obtains instantaneous power p from the product of instantaneous voltage v and instantaneous current i of a power system. In addition, since the instantaneous voltage and the instantaneous current of the alternating current vary sinusoidally with peaks and valleys, the instantaneous power does not have a constant value in a time scale shorter than the cycle of the alternating current. Therefore, alternating current power is generally represented by a time average value. For example, a power meter described in Patent Document 1 calculates and outputs active power Pₜ at time t as a moving average value of instantaneous power as in Equation (1).

$${P}_{t} = \frac{{P}_{t} + {P}_{t - 1} + {P}_{t - 2} + … + {P}_{t - N + 1}}{N} \qquad ( 1 )$$

The sample size N of the moving average is ideally set such that the length of the time window for the moving average is an integral multiple of the cycle of the alternating current. For example, when the instantaneous power is sampled 32 times in one cycle and the width of the window of the moving average is 10 cycles, N is 320.

It is assumed that the start point of the time window for moving average is 0 second and the end point is t1 (this is denoted as [0, t1]). On the other hand, it is assumed that the cycle of the alternating current is [0, T]. For example, in a case where t1<T, the instantaneous power in the section [t1, T] is not included in the moving average.

Therefore, when the instantaneous power reaches a peak in the section [t1, Y], the moving average value is biased to a side smaller than the true value. On the other hand, when the instantaneous power reaches a valley in the section [t1, T], the moving average value is biased to a side larger than the true value. One way to prevent bias is to let t1=T. However, since the frequency of the power system constantly fluctuates due to imbalance in power supply and demand, t1=T does not hold.

Therefore, in the related art, the width of the time window of the moving average is extended to, for example, 10 cycles to cope with the error due to the deviation of the cycle. Specifically, in Patent Document 1, a moving average of instantaneous power for 10 cycles is obtained, and active power is calculated based on the moving average.

In addition, power demand in offices, factories, general households, and the like varies from moment to moment. In order to contribute to the supply and demand adjustment of the power system, it is effective to increase the power supply (or decrease the power demand) when the power supply is insufficient, and it is effective to decrease the power supply (or increase the power demand) when the power supply is excessive. In this way, the sign of “increasing/decreasing” the power supply (or “decreasing/increasing” the power demand) is reversed depending on whether the power supply is insufficient or excessive at that time. Therefore, as in the case of the existing electricity meter, the positive and negative signs are cancelled out by simply integrating the electric power, and the contribution to the supply and demand adjustment cannot be measured. In order to measure the electric power that has contributed to the supply and demand adjustment of the electric power, it is necessary to consider the excess and deficiency of the electric power supply and demand at each time. Therefore, a technique for measuring the active power in a shorter time scale is required.

The supply and demand adjustment is mainly performed by adjusting the power generation amount so that the power plant keeps the frequency of the power system constant. Typically, a governor free operation represented by Equation (2) is performed.

$$Δ P = - \frac{1}{δ} \frac{{P}_{n}}{{f}_{n}} Δ f \qquad ( 2 )$$

In Equation (2), Pₙ is a rated power generation output (kW), and fₙ is a reference frequency (Hz) of the frequency of the power system. Δf is a deviation from a reference frequency (for example, 50 Hz or 60 Hz), and the generated power is reduced by ΔP in proportion thereto. δ is a value called a regulation rate, and the value is set in the control device of the power plant. In general, the regulation rate is set to a value of about 0.04. This specifies the relationship between the excess Δf with respect to the reference frequency and the power ΔP to be reduced with respect thereto. When the regulation rate is 0.04, if the frequency increases by 0.04×fₙ (Hz), ΔP decreases by Pₙ (kW). For example, in a case where the frequency increases by 0.04×fₙ (2.0 Hz when the reference frequency is 50 Hz) during the operation at the rated electric output, the power generation output is adjusted to reduce Δf to 0. The frequency of the power system is maintained constant by the power plant adjusting the power generation steeply in this manner.

In Equation (2), Δ is described as a deviation from the reference value. For example, it has been described that Δf is the deviation between the current frequency and the reference frequency. However, the same is true even in a case where Δ is the previous value. For example, it is assumed that the calculation of the metering is performed in a cycle of Δt seconds. At this time, even in a case where Δf is regarded as the difference between the frequency of the current calculation cycle and the frequency of the previous control cycle, and ΔP is regarded as the difference between the active power of the current control cycle and the active power of the previous calculation cycle, the Equation (2) is satisfied. Accordingly, as in Equation (2), the excess or deficiency of power supply and demand is metered by Δf, in a case where ΔP is positive when Δf is negative, the absolute value of ΔP is added because ΔP has contributed to the supply and demand adjustment, and in a case where ΔP is negative even when Δf is negative, the absolute value of ΔP is subtracted because ΔP has inhibited the supply and demand adjustment. For example, the power contributing to the supply and demand adjustment can be metered by Equation (3).

$$\begin{matrix}{M}_{t} = {\sum }_{τ = 1}^{t} - sgn ( Δ {f}_{τ} \cdot Δ {P}_{τ} ) \cdot \vert Δ {P}_{τ} \vert \cdot Δ t \\ = {\sum }_{τ = 1}^{t} - sgn ( Δ {f}_{τ} ) \cdot Δ {P}_{τ} \cdot Δ t\end{matrix} \qquad ( 3 )$$

In order to calculate Equation (3), the time difference ΔP of the active power is required. As described above, in the related art, the active power P is obtained as a moving average value of the frequency of the power system, and a section of the moving average is about 10 cycles. In a case where the frequency is 50 Hz, 10 cycles are 200 ms, so that the calculation of Equation (3) is performed every 200 ms.

### CITATION LIST

### Patent Literature

[PTL 1] Japanese Patent No. 5000441

### SUMMARY OF INVENTION

### Technical Problem

The governor free operation plays a central role in the supply and demand adjustment of the electric power system. In the future, the proportion of fluctuating power generation such as solar power generation and wind power generation will increase year by year toward the decarbonizing society, and it is necessary to improve the capability of the governor free operation in parallel to accept the fluctuation of the power generation amount.

Since the adjustment by governor free is autonomously performed in each power source without depending on a command, the adjustment power generated by the power source in a short cycle is not metered, is not settled, and the electric power provider cannot obtain compensation. Not only the governor free but also kinetic energy of a generator and an external combustion engine or an internal combustion engine connected thereto plays an important role. For example, when the frequency of the power system decreases, the rotational speed of the generator also decreases accordingly. However, a decrease in kinetic energy due to a variation in the rotational speed is supplied to the power system and functions as an adjustment power.

In order to enhance the supply and demand adjustment power of the electric power system, it is essential to meter the adjustment power of governor free or kinetic energy so that the compensation is given. However, for example, the power meter in the related art as disclosed in Patent Document 1 is not provided with a function of metering the adjustment power.

In addition, in order to stabilize the power system, it is valuable to exhibit the adjustment power without delay with respect to the fluctuation of the frequency, and a change in inertial energy acting on the side of suppressing the fluctuation of the system when the generator is synchronized with the frequency of the power system is also attracting attention as a fast supply and demand adjustment power (inertial force). In or der to measure a fast adjustment power such as an inertial force, the shorter the metering cycle of the power, the better. However, currently, the lower limit of the metering cycle is 200 ms as described above.

An object of the present disclosure is to provide an active power metering device, an adjustment power metering device, a metering method, and a program capable of improving responsiveness of power metering.

### Solution to Problem

According to an aspect of the present disclosure, an active power metering device includes: a frequency estimator configure to estimate a cycle and a frequency of an alternating current transmitted to or received from a power system by a target device based on a time series of a voltage of the alternating current; and an active power meter configured to calculate a moving average value of instantaneous power in a plurality of cycles of the alternating current for each cycle of the alternating current, and meter active power exchanged by the target device in one cycle of the alternating current from a difference between the calculated moving average value and a previously calculated moving average value.

According to an aspect of the present disclosure, an active power metering device includes: a frequency estimator configure to estimate a cycle and a frequency of an alternating current based on a time series of a voltage of the alternating current transmitted to or received from a power system by a target device; and an active power meter configured to meter active power exchanged by the target device from an integrated value of instantaneous power in one cycle of the alternating current.

According to an aspect of the present disclosure, an active power metering device includes: a frequency estimator configured to estimate a cycle and a frequency of a n alternating current transmitted to or received from a power system by a target device based on a time series of a voltage of the alternating current; and an active power meter including an instantaneous power calculator configured to calculate instantaneous power of the alternating current at a frequency that is an integral multiple of the frequency of the alternating current, and output a discrete time signal of the instantaneous power in one cycle of the alternating current, and a finite impulse response filter having a Hanning window whose tap length matches a calculation frequency of the instantaneous power as a coefficient, the active power meter being configured to filter a discrete signal of the instantaneous power with the finite impulse response filter and meter active power exchanged by the target device.

According to an aspect of the present disclosure, an active power metering device includes: a frequency estimator configured to estimate a cycle and a frequency of a n alternating current based on a time series of a voltage of the alternating current trans mitted to or received from a power system by a target device; an instantaneous power calculator configured to calculate an instantaneous power of the alternating current at a frequency that is an integral multiple of the frequency of the alternating current, and output a discrete time signal of the instantaneous power in one cycle of the alternating current; and an active power meter configured to filter a discrete signal of the instantaneous power with a finite impulse response filter that cuts off a component corresponding to a vibration frequency of the alternating current, and meter active power exchanged by the target device.

According to an aspect of the present disclosure, an active power metering device includes: a frequency estimator configured to estimate a frequency of an alternating current of at least one phase of a three-phase alternating current transmitted to or received from a power system by a target device based on a time series of a voltage of the three-phase alternating current; and an active power meter configured to meter active power of all three phases of the target device from a moving average value of a sum of instantaneous power of each phase of the three-phase alternating current.

According to an aspect of the present disclosure, an active power metering device includes: a synchronous motor model configured to receive, as an input, an instantaneous voltage of an alternating current transmitted to or received from a power system by a target device, calculate a rotation speed of a synchronous motor included in the target device, and output a frequency of the alternating current; and an active power meter configured to meter active power exchanged by the target device in one cycle of the alternating current based on an instantaneous current of the alternating current, the instantaneous voltage, and the frequency output from the synchronous motor model.

According to an aspect of the present disclosure, an adjustment power metering device includes: the active power metering device according to any one of the above described aspects; and an adjustment power amount meter configured to calculate a supply and demand adjustment power of the target device based on a temporal difference of the active power and a temporal difference of the frequency.

According to an aspect of the present disclosure, a metering method includes: a step of estimating a cycle and a frequency of an alternating current based on a time series of a voltage of the alternating current transmitted to or received from a power system by a target device; a step of calculating instantaneous power of the alternating current at a frequency that is an integral multiple of the frequency of the alternating current, and outputting a discrete time signal of the instantaneous power in one cycle of the alternating current; and a step of metering active power exchanged by the target device by filtering a discrete signal of the instantaneous power with a finite impulse response filter having a Hanning window whose tap length matches a calculation frequency of the instantaneous power as a coefficient.

According to an aspect of the present disclosure, a program causes an active power metering device to execute: a step of estimating a cycle and a frequency of an alternating current based on a time series of a voltage of the alternating current transmitted to or received from a power system by a target device; a step of calculating instantaneous power of the alternating current at a frequency that is an integral multiple of the frequency of the alternating current, and outputting a discrete time signal of the instantaneous power in one cycle of the alternating current; and a step of metering active power exchanged by the target device by filtering a discrete signal of the instantaneous power with a finite impulse response filter having a Hanning window whose tap length matches a calculation frequency of the instantaneous power as a coefficient.

### Advantageous Effects of Invention

According to the above aspects, it is possible to improve the responsiveness of power measurement.

### BRIEF DESCRIPTION OF DRAWINGS

FIG. 1 is a diagram showing a functional configuration of an adjustment power metering device according to a first embodiment.

FIG. 2 is a first diagram for describing a function of an active power metering device according to the first embodiment.

FIG. 3 is a second diagram for describing the function of the active power metering device according to the first embodiment.

FIG. 4 is a diagram showing a functional configuration of a frequency estimator according to a Modification Example 1 of the first embodiment.

FIG. 5 is a diagram showing a functional configuration of an adjustment power metering device according to a Modification Example 2 of the first embodiment.

FIG. 6 is a diagram for describing a function of an active power metering device according to the Modification Example 2 of the first embodiment.

FIG. 7 is a diagram showing a functional configuration of an adjustment power metering device according to a Modification Example 3 of the first embodiment.

FIG. 8 is a diagram showing a functional configuration of an active power meter according to a second embodiment.

FIG. 9 is a first diagram for describing a function of the active power metering device according to the second embodiment.

FIG. 10 is a second diagram for describing the function of the active power metering device according to the second embodiment.

FIG. 11 is a third diagram for describing the function of the active power metering device according to the second embodiment.

FIG. 12 is a fourth diagram for describing the function of the active power metering device according to the second embodiment.

FIG. 13 is a diagram for describing a function of the active power metering device according to a third embodiment.

FIG. 14 is a diagram showing a functional configuration of an active power meter according to a fourth embodiment.

FIG. 15 is a diagram showing a functional configuration of an active power meter according to a Modification Example of a fifth embodiment.

FIG. 16 is a diagram showing a functional configuration of an adjustment power metering device according to a sixth embodiment.

FIG. 17 is a diagram showing a functional configuration of an adjustment power metering device according to an eighth embodiment.

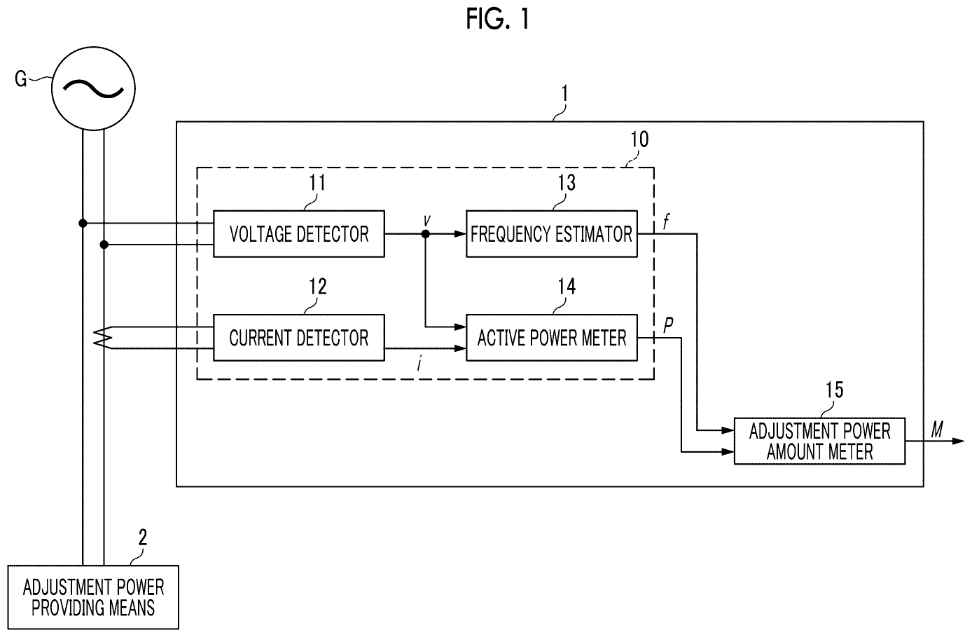

FIG. 1δ is a schematic block diagram showing a configuration of a computer according to at least one embodiment.

### DESCRIPTION OF EMBODIMENTS

### First Embodiment

Hereinafter, the first embodiment will be described in detail with reference to FIGS. 1 to 3.

### (Functional Configuration of Adjustment Power Metering Device)

FIG. 1 is a diagram showing a functional configuration of an adjustment power metering device according to a first embodiment.

As shown in FIG. 1, an adjustment power providing means 2 is connected to the alternating current power system G. The adjustment power providing means 2 is a generator or a load. The adjustment power metering device 1 is provided, for example, at a connection point between the alternating current power system G and the adjustment power providing means 2. The adjustment power metering device 1 according to the present embodiment meters the supply and demand adjustment performed by the adjustment power providing means 2 on the alternating current power system G as the adjustment power amount.

The adjustment power metering device 1 includes an active power metering device 10 and an adjustment power amount meter 15. The active power metering device 10 includes a voltage detector 11, a current detector 12, a frequency estimator 13, and an active power meter 14.

The voltage detector 11 outputs a voltage signal v that is a metering value of a voltage of power transmitted to or received from the alternating current power system G by the adjustment power providing means 2. For example, the voltage detector 11 meters a voltage at a connection point between the alternating current power system G and the adjustment power providing means 2 or at inlet and outlet of the adjustment power providing means 2 on the alternating current power system G side.

The current detector 12 outputs a current signal i that is a metering value of a current of power transmitted to or received from the alternating current power system G by the adjustment power providing means 2. For example, the current detector 12 meters a current at a connection point between the alternating current power system G and the adjustment power providing means 2 or at the inlet and outlet of the adjustment power providing means 2 on the alternating current power system G side.

The frequency estimator 13 estimates the cycle and frequency f of the alternating current exchanged between the adjustment power providing means 2 and the alternating current power system G, based on the time series of the voltage signal v.

The active power meter 14 meters the active power P of the power exchanged between the adjustment power providing means 2 and the alternating current power system G from the moving average value of the instantaneous power in a plurality of cycles of the alternating current.

The adjustment power amount meter 15 calculates the supply and demand adjustment power M of the power based on the temporal difference in active power and the temporal difference in frequency.

### (Processing of Adjustment Power Metering Device)

Next, processing of the adjustment power metering device 1 will be described in detail.

The active power meter 14 reads the voltage signal v and the current signal i at least every calculation cycle of the active power. The active power meter 14 calculates instantaneous active power pₜ at time t (hereinafter also simply referred to as “instantaneous power”) from the voltage signal vₜ at time t and the current signal iₜ at time t. In addition, the active power meter 14 outputs, as the active power Pₜ, a value obtained by performing a moving average of the instantaneous power pₜ at each time retroactively to the past, as in the above-described Equation (1).

In the present embodiment, the calculation cycle of the active power is set to match with the cycle of the alternating current. For example, in a case where the reference frequency of the alternating current power system G is 50 Hz, the calculation cycle of the active power is 20 ms. The active power meter 14 calculates the instantaneous power p 32 times per cycle. In addition, the active power meter 14 calculates the active power P by performing a moving average of the instantaneous power p for 10 cycles for each calculation cycle.

The frequency estimator 13 receives the voltage signal v and calculates the frequency f of the alternating current from the time intervals at which the voltage v alternately crosses zero. The voltage v has two crossings in one cycle, one crossing from a positive voltage to a negative voltage and the other crossing from a negative voltage to a positive voltage. In a temporal section (a section corresponding to 10 cycles) of the moving average of Equation (1), when the time of a first crossing is denoted by t_{X, start-1}, the time of a last crossing is denoted by t_{X, start}, and the number of crossings is denoted by n_{X}, the frequency of the moving average section of Equation (1) can be calculated by the following Equation (4). Taking into account the direction of crossing, for example, in a case where only the voltage crosses zero from positive to negative is taken, the crossing is once per cycle and ½ times the right hand side of Equation (9) is unnecessary.

$${f}_{t} = \frac{1}{2} \frac{{n}_{X}}{{t}_{X , start} - {t}_{X , start - 1}} \qquad ( 4 )$$

The adjustment power amount meter 15 obtains a difference between the active power P and the frequency f of the previous time (time t−1) for each time width N of the moving average of Equation (1) by Equations (5) and (6).

$${Δ}_{N} Δ {P}_{t} = {P}_{t} - {P}_{t - 1} \qquad ( 5 )$$

$${Δ}_{N} Δ {f}_{t} = {f}_{t} - {f}_{t - 1} \qquad ( 6 )$$

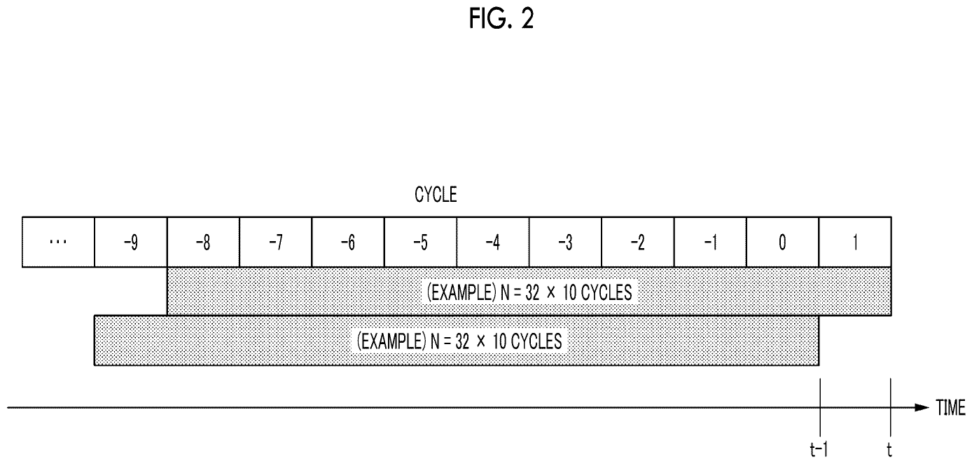

FIG. 2 is a first diagram for describing a function of the active power metering device according to the first embodiment.

For example, as shown in FIG. 2, the active power Pₜ is a moving average value of the instantaneous power p in the past 10 cycles (cycles 1, 0, −1, −2, . . . , and −8) from the time t, and the active power Pₜ₋₁ is a moving average value of the instantaneous power p in the past 10 cycles (cycles 0, −1, −2, −3, . . . , and −9) from the previous cycle. The frequency fₜ is an average value of the frequencies in the past 10 cycles (cycles 1, 0, −1, −2, . . . , and −8) from the time t. The frequency fₜ₋₁ is an average value of frequencies in the past 10 cycles (cycles 0, −1, −2, −3, . . . , and −9) from the previous cycle. That is, the adjustment power amount meter 15 obtains the difference ΔP between the moving average values of the active power P and the difference Δf between the average values of the frequency f in two cycles shifted by one cycle.

Then, the adjustment power amount meter 15 calculates the adjustment power M by Equation (3).

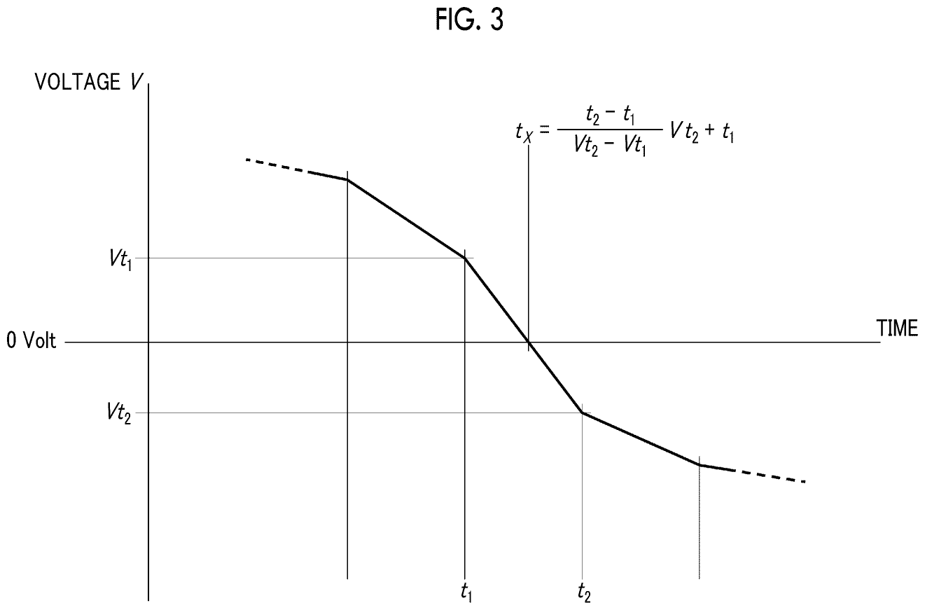

FIG. 3 is a second diagram for explaining the function of the active power metering device according to the first embodiment.

The calculation of the voltage crossing time tₓ will be described with reference to FIG. 3. As shown in FIG. 3, the voltage crosses 0 V between time t₁ and time t₂ when the sign of the voltage is inverted at adjacent times. The crossing time t_{X} is calculated by the following Equation (7).

$${t}_{X} = \frac{{t}_{2} - {t}_{1}}{{v}_{{t}_{2}} - {v}_{{t}_{1}}} {v}_{{t}_{2}} + {t}_{1} \qquad ( 7 )$$

### (Actions and Effects)

The adjustment power metering device 1 according to the first embodiment includes a frequency estimator 13 that estimates a cycle and a frequency of an alternating current transmitted or received by the adjustment power providing means 2 based on a time series of a voltage v of the alternating current, an active power meter 14 that meters active power P from a moving average value of instantaneous power p in a plurality of cycles (for example, 10 cycles) of the alternating current, and an adjustment power amount meter 15 that calculates a supply and demand adjustment power M of power based on each temporal difference (difference in one cycle) between the active power P and the frequency.

In this way, the adjustment power metering device 1 can obtain the difference for each cycle of the alternating current for the active power P and the frequency f, and calculate the supply and demand adjustment power M for each cycle from these differences. For example, when the reference frequency of the alternating current is 50 Hz, one cycle is 20 ms. Therefore, the adjustment power metering device 1 can improve the responsiveness of metering. Accordingly, the adjustment power metering device 1 can measure a fast adjustment power such as an inertial force.

FIG. 1 shows an example in which the active power metering device 10 is provided inside the adjustment power metering device 1, but the present invention is not limited thereto. In another embodiment, the active power metering device 10 may be provided independently as a device separate from the adjustment power metering device 1. For example, the active power metering device 10 is provided on a power line connected to an outlet of a generator, and meters the active power P of power transmitted by the generator. In still another embodiment, the active power metering device 10 is provided on a power line connected to an inlet of a load and meters the active power P of power received by the load. The generator or the load is an example of a target device whose active power is metered by the active power metering device 10. In addition, in this case, the active power meter 14 of the active power metering device 10 meters the active power that the target device exchanges in a cycle of the alternating current by Equation (5). As a result, it is possible to improve the responsiveness of the metering of the active power. The active power for one cycle metered by the active power metering device 10 is used, for example, for automatic output control in a control device of a generator. Since the active power metering device 10 can meter the active power of the generator without delay, the control performance of the generator can also be improved.

### Modification Example 1

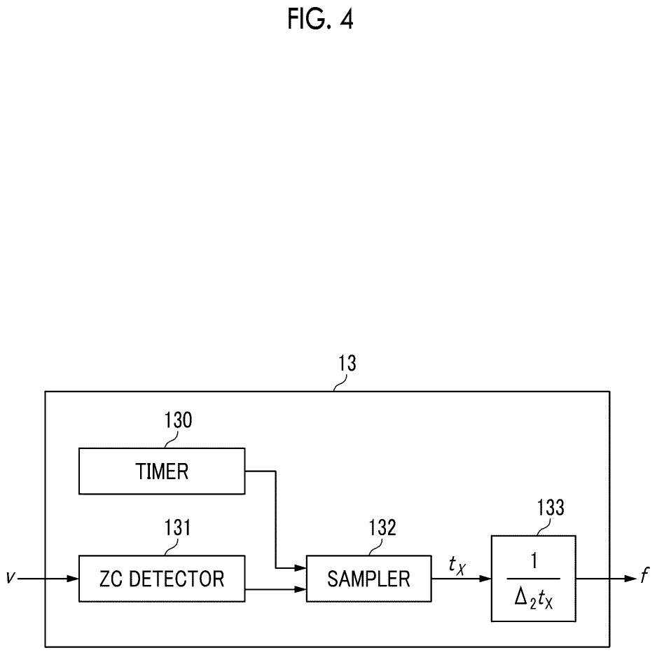

FIG. 4 is a diagram showing a functional configuration of a frequency estimator according to a Modification Example 1 of the first embodiment.

As shown in FIG. 4, the frequency estimator 13 may obtain the crossing time t_{X} by using a zero crossing detector 131 (hereinafter, also referred to as a “ZC detector”).

The output of the ZC detector 131 changes stepwise at the moment when the voltage signal crosses 0 V. The output of the ZC detector 131 and the time of the timer 130 are input to the sampler 132. The sampler 132 outputs the time of the timer 130 at the moment when the output of the ZC detector 131 changes stepwise. The output time corresponds to t_{X}. There are two zero crossings in one cycle. Therefore, the difference between the previous t_{X} and the current t_{X} corresponds to one cycle. The frequency calculation unit 133 calculates the reciprocal of Δ₂t_{X} as the frequency f, the Δ₂t_{X} being the difference between the previous t_{X} and the current t_{X}.

### Modification Example 2

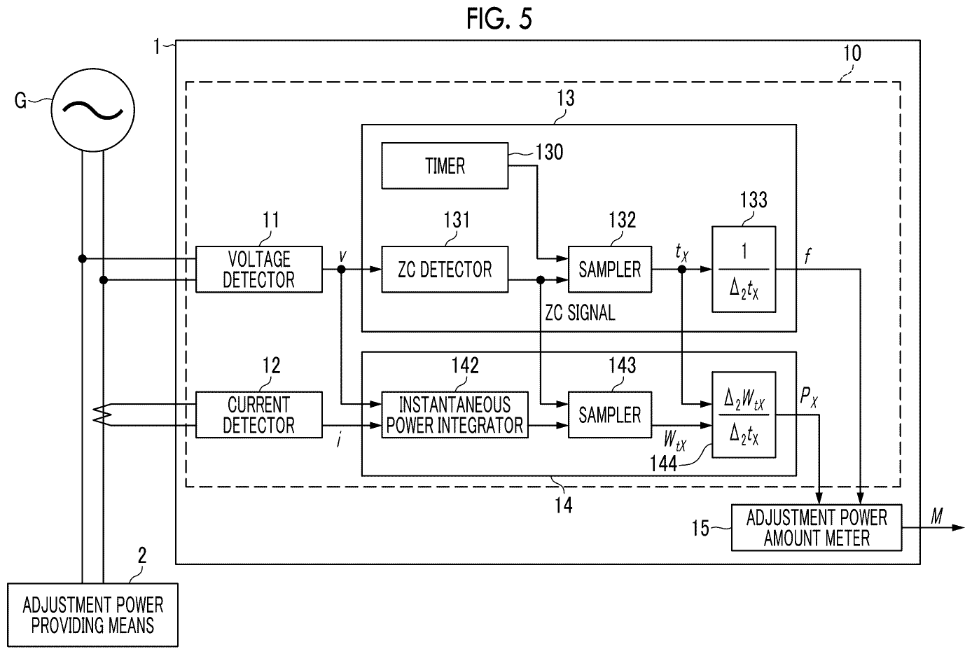

FIG. 5 is a diagram showing a functional configuration of an adjustment power metering device according to a Modification Example 2 of the first embodiment.

As shown in FIG. 5, the active power meter 14 may include an instantaneous power integrator 142, a sampler 143, and an active power calculation unit 144. The frequency estimator 13 of the Modification Example 1 is used.

The instantaneous power vibrates at 2f, which is twice the frequency f of the alternating current. Therefore, when the instantaneous power is moving-averaged for ½f second, which is the vibration cycle of the instantaneous power, or an integral multiple of ½f second, the vibration component is canceled out, and the active power, which is the average value of the instantaneous power, can be obtained.

According to the related art, for example, the instantaneous power is moving-averaged for a cycle of 10 cycles of the reference frequency to obtain the active power. Since the frequency of the alternating current power system constantly fluctuates, the cycle of one cycle also constantly fluctuates. Therefore, in the related art, approximation is performed by averaging in a cycle of 10 cycles. In this way, the responsiveness of the active power detection deteriorates. As long as the power meter is used for the purpose of charging electricity, responsiveness is not important. For example, it is sufficient to know a value obtained by integrating power for one month. However, in order to accurately measure the adjustment power exerted by the governor free, the inertia, or the system stabilizing device, it is meaningful to estimate one cycle of the alternating current and accurately calculate the active power of one cycle.

In the first embodiment, for example, the active power is calculated from the moving average of 10 cycles of the alternating current. In a case where the reference frequency of the alternating current is 50 Hz, the width of the time window of the moving average is 200 ms. In the Modification Example 2, the width of the time window of the moving average can be set to one cycle (20 ms). As a result, it is possible to measure a component having a fast power for supply and demand adjustment.

Details of the processing will be described with reference to FIG. 5. The difference from the first embodiment is that the active power is measured for each cycle. In the Modification Example 2, the active power is represented by P_{X} in order to emphasize that the metering is performed for each cycle.

Since there are two zero crossings in one cycle, the active power P_{X} is integrated by the following Equation (8) from the difference of the power amount for every two zero crossings.

$$\begin{matrix}{P}_{X} = \frac{1}{{t}_{X} - {t}_{X , prev 2}} {\int }_{{t}_{X , prev 2}}^{{t}_{X}} vidt \\ = \frac{1}{{t}_{X} - {t}_{X , prev 2}} ( {\int }_{0}^{{t}_{X}} v i d t - {\int }_{0}^{{t}_{X , prev 2}} vidt ) \\ = \frac{{W}_{tX} - {W}_{tX , prev 2}}{{t}_{X} - {t}_{X , prev 2}} \\ = \frac{{Δ}_{2} {W}_{t X}}{{Δ}_{2} {t}_{X}}\end{matrix} \qquad ( 8 )$$

Here, t_{X} is the time of the most recent zero cross, t_{X,prev2} is the time of the second previous zero cross, and W_{tX} is the amount of power at time t_{X}.

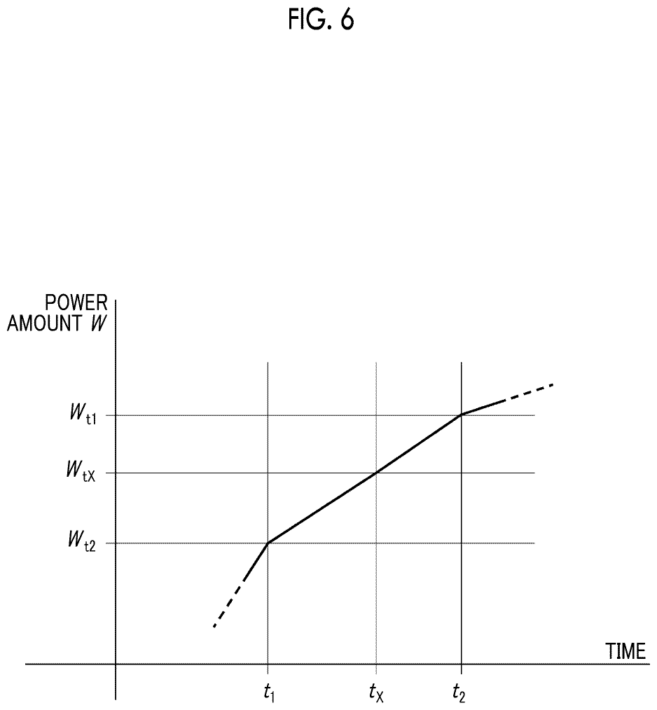

FIG. 6 is a diagram for describing a function of an active power metering device according to the Modification Example 2 of the first embodiment.

As shown in FIG. 6, when t₁ is the time of the integration operation immediately before the zero cross and t₂ is the time of the integration operation immediately after the zero cross, W_{tX} is determined by the following Equation (9).

$${W}_{{t}_{X}} = \frac{{W}_{{t}_{2}} - {W}_{{t}_{1}}}{{t}_{2} - {t}_{1}} ( {t}_{X} - {t}_{1} ) + {W}_{{t}_{1}} \qquad ( 9 )$$

When the difference for every two zero crossings is denoted by Δ₂, the adjustment power amount for every two crossings (that is, once in one cycle) may be calculated by the following Equation (10).

$${M}_{{t}_{X}} = {\sum }_{τ = 1 , 3 , 5 , … , {t}_{X}} - sgn ( {Δ}_{2} {f}_{τ} ) \cdot {Δ}_{2} {P}_{{X}_{τ}} \cdot {Δ}_{2} {f}_{{X}_{τ}} \qquad ( 10 )$$

Alternatively, the adjustment power amount may be calculated by the following Equation (11) for each crossing. Δ is a difference for each zero crossing.

$${M}_{{t}_{X}} = {\sum }_{τ = 12 , 3 , … , {t}_{X}} - sgn ( Δ {f}_{τ} ) \cdot Δ {P}_{{X}_{τ}} \cdot Δ {t}_{{X}_{τ}} \qquad ( 11 )$$

According to the Modification Example 2, the active power per cycle of the alternating current can be accurately calculated. This makes it possible to meter the adjustment power for power supply and demand for each cycle of alternating current. As a result, it is possible to meter a component having a fast adjustment power, for example, derived from an inertial force.

### Modification Example 3

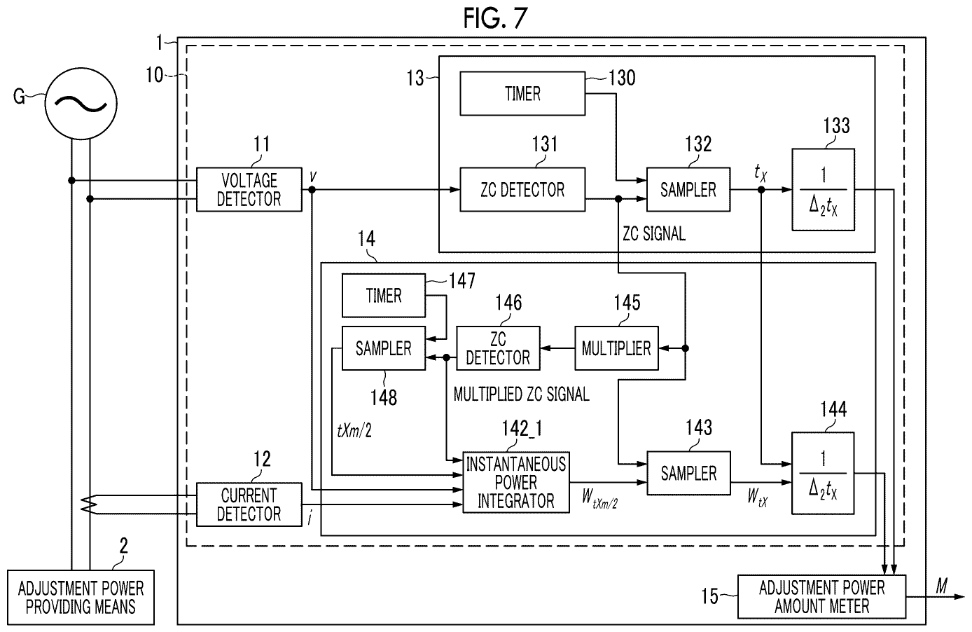

FIG. 7 is a diagram showing a functional configuration of an adjustment power metering device according to a Modification Example 3 of the first embodiment.

The calculation of the instantaneous power integrator 142 of the Modification Example 2 is not strictly synchronized with the cycle of the alternating current. Therefore, the power amount W_{tX} at the zero-crossing time t_{X} is estimated by performing the interpolation and approximation of Equation (9). In the Modification Example 3, the calculation of the instantaneous power integrator 142 is made to match with the cycle of the alternating current, thereby eliminating the need for interpolation and approximation. As shown in FIG. 7, the instantaneous power integrator 142_1 receives the multiplied ZC signal. The multiplied ZC signal is a signal obtained by multiplying the frequency of the ZC signal by the multiplier 145. For example, in a case where the ZC signal is 100 Hz, the multiplied ZC signal is 320 Hz. Further, the phase of the multiplied ZC signal is adjusted by the ZC detecting unit 146 so that the multiplied ZC signal is turned on at the same time as the ZC signal is turned on.

The instantaneous power integrator 142_1 calculates the instantaneous power p from the voltage v and the current i based on the multiplied ZC signal, and outputs the integrated value W_{tXm/2} of the active power. The integration calculation requires the cycle of the multiplied ZC signal, which is obtained from the time t_{Xm} at which the multiplied ZC signal output from the timer 147 and the sampler 148 is turned on. According to such a calculation processing, since the cycle of the alternating current and the calculation cycle of the integrated value W_{tXm/2} of the active power are synchronized with each other, the interpolation and approximation of Equation (8) is unnecessary, and the calculation is simple.

### Second Embodiment

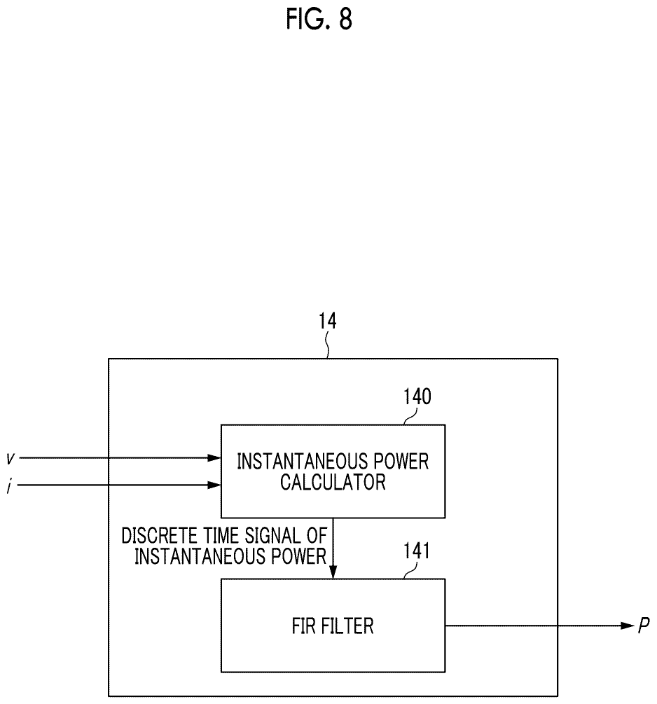

Next, a second embodiment will be described in detail with reference to FIGS. 8 to 12. The same components as those of the above-described embodiment are denoted by the same reference numerals, and detailed description thereof will be omitted.

### (Functional Configuration of Active Power Meter)

FIG. 8 is a diagram showing a functional configuration of an active power meter according to a second embodiment.

As shown in FIG. 8, in the adjustment power metering device 1 according to the present embodiment, the active power meter 14 includes an instantaneous power calculator 140 and a finite impulse response filter 141 (hereinafter also referred to as “FIR filter”).

The instantaneous power calculator 140 calculates the instantaneous power of the alternating current at a frequency fₛ (sampling frequency) that is an integral multiple m of the frequency f of the alternating current, and outputs a discrete time signal of the instantaneous power in one cycle of the alternating current.

The FIR filter 141 uses, as a coefficient, a Hanning window in which the tap length is matched with (m+1) obtained by adding 1 to the calculation frequency m of the instantaneous power. The FIR filter 141 filters the discrete time signal of the instantaneous power input from the instantaneous power calculator 140 and outputs active power.

### (Processing of Active Power Meter)

The second embodiment is different from the first embodiment in that the active power meter 14 sets the calculation frequency fₛ to an integral multiple m of the frequency f of the alternating current power and uses an FIR filter 141 having a Hanning window with a tap length of m+1 as a coefficient instead of the moving average. In the present embodiment, a reference frequency (for example, 50 Hz) is used as the frequency f of the alternating current power.

The moving average processing of Equation (1) used in the first embodiment is the same as multiplying instantaneous power by a rectangular window function. Therefore, Equation (1) can be expressed as Equation (13) by the weighting factor w∈R^{N} of the rectangular window having the length N shown in Equation (12).

$$\begin{matrix}w = \{ \frac{1}{N} , \frac{1}{N} , \frac{1}{N} , … , \frac{1}{N} \} \\ = {\{ \frac{1}{N} \}}_{k = 0}^{N - 1}\end{matrix} \qquad ( 12 )$$

$${P}_{t} = {\sum }_{k = 0}^{N - 1} {w}_{k} {p}_{t - k} \qquad ( 13 )$$

In a case where the instantaneous power is sampled 32 times for one cycle, that is, m is 32 and the width of the window of the moving average is 10 cycles, the value of N is 320. In a case where the number of instantaneous power samples per cycle is set to an integer m, the sampling frequency fₛ is m times the frequency f.

In the second embodiment, a Hanning window is used. The length of the Hanning window is m+1. The weighting factor h∈R^{m+1} of the Hanning window is expressed by the following Equation (14).

$${W}_{H} = {\{ 0.5 - 0.5 cos \frac{2 π k f}{{f}_{s}} \}}_{k = 0}^{m} \qquad ( 14 )$$

Since the steady gain of the signal decreases due to the Hanning window, the signal is corrected with a correction coefficient CH as in Equation (15).

$${c}_{H} = {\sum }_{k = 0}^{m} {w}_{{H}_{k}} \qquad ( 15 )$$

Finally, the weighting factor of the Hanning window is expressed by the following Equation (16).

$$h = \frac{1}{{c}_{H}} {\{ 0.5 - 0.5 cos \frac{2 π k f}{{f}_{s}} \}}_{k = 0}^{m} \qquad ( 16 )$$

The active power by the Hanning window is expressed by the following Equation (17).

$${P}_{t} = {{\sum }^{m - 1}}_{k = 0} {h}_{k} {p}_{t - k} \qquad ( 17 )$$

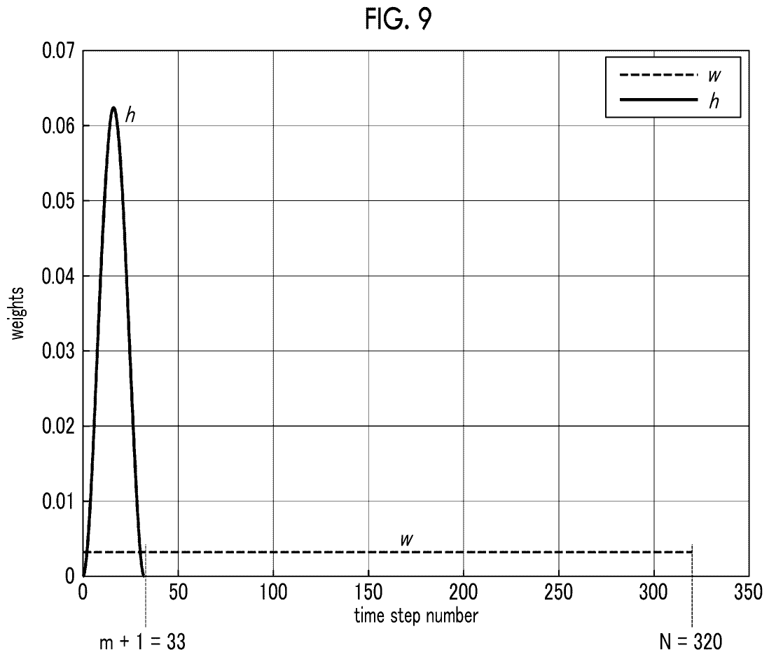

FIG. 9 is a first diagram for describing the function of the active power metering device according to the second embodiment.

FIG. 9 is a comparative example of the Hanning window function h after the ga in correction and the rectangular window function w of the moving average. The length of the Hanning window is m+1=33 in time steps, which is approximately 1/10 of the length N=320 of the rectangular window.

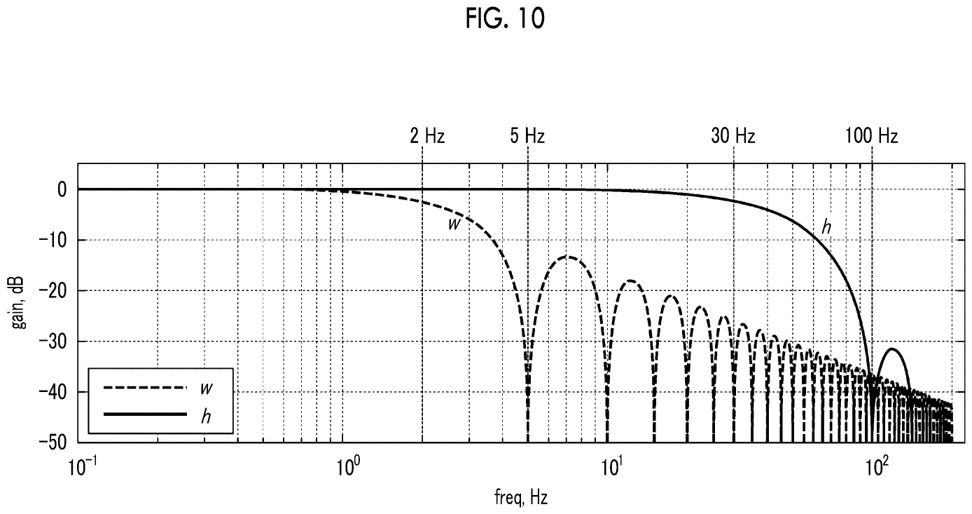

FIG. 10 is a second diagram for describing the function of the active power metering device according to the second embodiment.

FIG. 10 is a comparative example of the frequency characteristics of the response of the active power P to the instantaneous power p of the Hanning window and the rectangular window. In the rectangular window, the response gain decreases from around 2 Hz. On the other hand, in the Hanning window, since the gain does not decrease up to about 30 Hz, the Hanning window is superior to the rectangular window in responsiveness.

Further, in the rectangular window, there are response valleys at 5 Hz, 10 Hz, 15 Hz, 20 Hz, 25 Hz, and . . . . This means that even in a case where the instantaneous power fluctuates at, for example, 5 Hz, the fluctuation is not observed as a fluctuation in the active power, which is not preferable in the metering of the supply and demand adjustment power of the power.

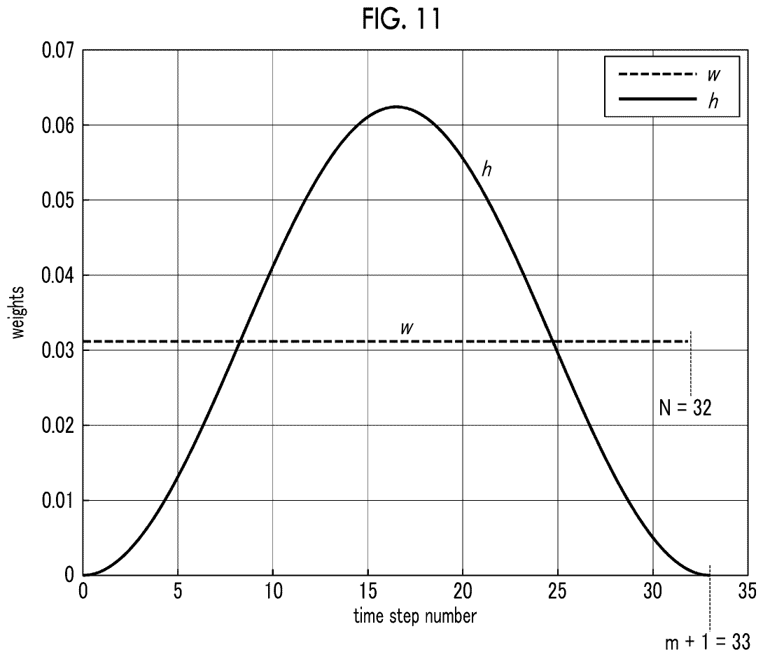

FIG. 11 is a third diagram for describing the function of the active power metering device according to the second embodiment.

Further, in order to show that the difference between the Hanning window and the rectangular window is not simply caused by the difference between the lengths of the window functions, the rectangular window is changed to N=32 corresponding to the length of one cycle and evaluated. FIG. 11 shows a comparative example of a rectangular window function w having a length N=32 and a Hanning window function h having a length m+1=33.

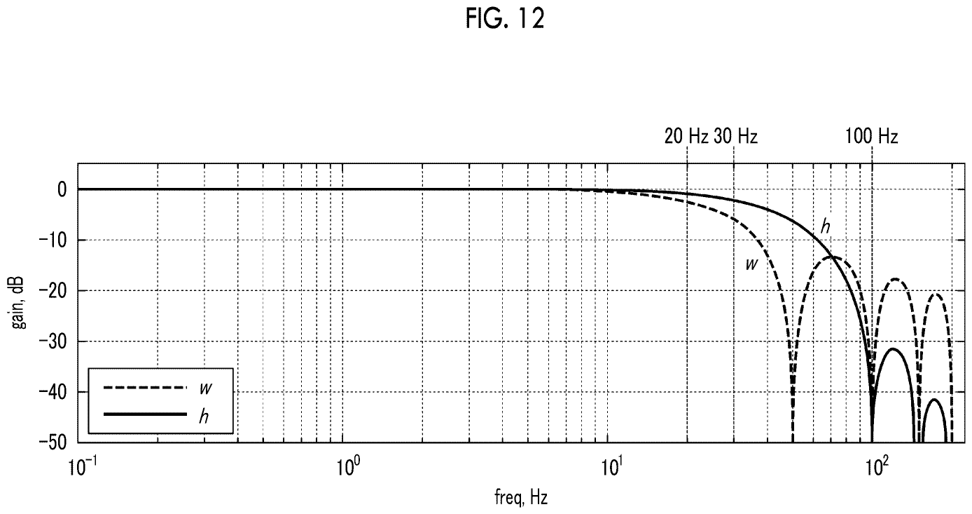

FIG. 12 is a fourth diagram for describing the function of the active power metering device according to the second embodiment.

FIG. 12 shows a comparative example of the frequency characteristics of the rectangular window w and the Hanning window h when the length of the rectangular window w is changed to N=32. While the gain of the rectangular window w decreases from 20 Hz, the gain of the Hanning window h starts from 30 Hz. Therefore, the Hanning window can measure up to a higher frequency than the rectangular window.

Further, the instantaneous power of the single-phase alternating current vibrates at twice the frequency of the alternating current. In the alternating current power system G of 50 Hz, the vibration of the instantaneous power corresponds to 100 Hz. Since both the Hanning window and the rectangular window have a valley of the response gain in the vicinity of 100 Hz, the function of removing the vibration is recognized. Comparing the two, since the Hanning window has a wider valley width than the rectangular window, even when the frequency of the alternating current fluctuates, the same vibration can be better removed. Further, since the response gain of the Hanning window at frequencies around 100 Hz is smaller than that of the rectangular window by about 10 dB (about ⅓ times the gain), the Hanning window is more suitable for measuring the active power.

### (Actions and Effects)

The adjustment power metering device 1 according to the second embodiment includes, instead of the active power metering device of the first embodiment, an active power metering device 14 that includes an instantaneous power calculator 140 that calculates the instantaneous power of the alternating current at a frequency that is an integral multiple of the frequency of the alternating current and outputs a discrete time signal of the instantaneous power in one cycle of the alternating current, and an FIR filter 141 that uses a Hanning window having a tap length matched with the calculation frequency of the instantaneous power calculator 140 as a coefficient, filters the discrete signal of the instantaneous power with the FIR filter, and meters the active power P.

In the active power meter according to the first embodiment, for example, it is necessary to perform the moving average of 10 cycles of the alternating current. In contrast, the active power meter 14 according to the second embodiment can calculate the active power in only one cycle, and thus can further improve the responsiveness of the active power metering. As a result, the adjustment power metering device 1 can meter a component having a fast supply and demand adjustment power of the power.

In addition, the adjustment power metering device 1 according to the second embodiment can more effectively remove fluctuations in instantaneous power than the first embodiment. Thus, the adjustment power metering device 1 can accurately meter the supply and demand adjustment power of the power.

### Third Embodiment

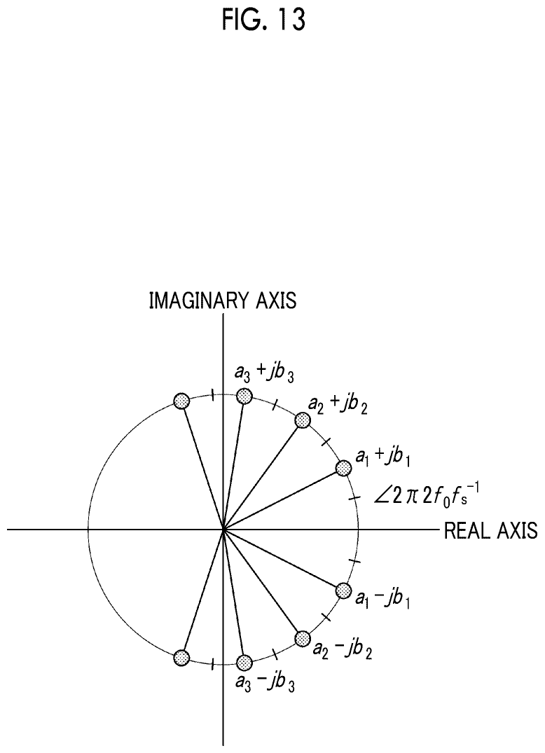

Next, a third embodiment will be described in detail with reference to FIG. 13. The same components as those of the above-described embodiment are denoted by the same reference numerals, and detailed description thereof will be omitted.

In the second embodiment, the example in which the FIR filter having the Hanning window in which the tap length is matched with the calculation frequency (m+1) of the instantaneous power as the coefficient is used has been described. In contrast, the third embodiment is characterized by using an FIR filter 141 that cuts off a component corresponding to a frequency 2f (vibration frequency) twice the frequency f of the alternating current. In the present embodiment, a reference frequency (for example, 50 Hz) is used as the frequency f of the alternating current power.

### (Processing of Active Power Meter)

An FIR system discretized at frequency fₛ is considered. The FIR system is represented by a transfer function H(z) of Equation (18). Here, m is the tap length of the FIR filter 141. The determination of m will be described later.

$$H ( z ) = \frac{{h}_{0} {z}^{m} + {h}_{1} {z}^{m - 1} + … + {h}_{m - 1} {z}^{1 m} + {h}_{m}}{{z}^{m}} \qquad ( 18 )$$

The frequency response of the FIR filter 141 is known from the transfer function. For example, in order to obtain the gain with respect to the frequency f, the absolute value of a complex number obtained by substituting z=exp(±j2πffₛ⁻¹) into H may be taken as in Equation (19).

$$\vert H ( {e}^{\pm j \frac{2 π f}{{f}_{s}}} ) \vert = \vert \frac{{{h}_{0} ( {e}^{\pm \frac{- 2 π f}{{f}_{s}}} )}^{m} + {{h}_{1} ( {e}^{\pm j \frac{2 π f}{{f}_{s}}} )}^{m - 1} + … + {{h}_{m - 1} ( {e}^{\pm j \frac{2 π f}{{f}_{s}}} )}^{1 m} + {h}_{m}}{{( {e}^{\pm j \frac{2 π f}{{f}_{s}}} )}^{m}} \vert \qquad ( 19 )$$

It is known in advance that single-phase instantaneous power vibrates at a fundamental frequency of 2f, which is twice the frequency f of alternating current. Hereinafter, 2f is also referred to as a vibration frequency of the alternating current. For example, it is assumed that the current i and the voltage v are both represented by cos(2πft). At this time, the instantaneous power is represented by Equation (20), and vibrates at a frequency 2f around ½.

$$\begin{matrix}v \times i = cos 2 π ft \times cos 2 π ft \\ = \frac{1}{2} + \frac{1}{2} cos 2 π2 ft\end{matrix} \qquad ( 20 )$$

The active power is a time average value represented by the first term on the right hand side. The purpose of the FIR filter 141 is to remove the second term on the right hand side and leave the first term on the right hand side. In order to remove the second term on the right hand side, it is sufficient that the value of the numerator polynomial of the transfer function H(z) becomes 0 at z=exp(±j2πffₛ⁻¹). The solution of the numerator polynomial=0 of the transfer function is called a zero point. When a zero point is arranged at exp(±j2πffₛ⁻¹) on the unit circle of the complex plane, the transfer function becomes 0 at 2π·2fHz, and the component of 2π·2fHz can be cut off.

FIG. 13 is a diagram for describing a function of the active power metering device according to the third embodiment.

In order to set a plurality of cutoff frequencies, as shown in FIG. 13, a zero point may be arranged at {a₁±jb₁, a₂±jb₂, . . . , a_{m/2}±jb_{m/2}} which is a position on the unit circle of the complex plane of the FIR filter 141. For example, in a case where {2f₀, 4f₀, 6f₀} Hz, which are harmonic components twice, four times, and six times the instantaneous power, is to be cut off, the zero point is determined as in the following Equation (21).

$$\{ {a}_{1} + j {b}_{1} , {a}_{2} + j {b}_{2} , {a}_{3} + j {b}_{3} \} = \{ {e}^{\pm j \frac{2 π 2}{m}} , {e}^{\pm j \frac{2 π 4}{m}} , {e}^{\pm j \frac{2 π 6}{m}} \} \qquad ( 21 )$$

A provisional FIR filter is determined from the zero point. In the provisional FIR filter, the numerator polynomial of the transfer function is N(z), the denominator polynomial is D(z), and the whole is represented by N(z)/D(z).

When the number of zero points is m, the tap length of the provisional FIR filter is m+1. In this example, m=6, and the tap length of the provisional FIR is m+1=7. The numerator of the provisional FIR filter is determined according to the zero point. The polynomial of the numerator of the FIR filter is the following Equation (22).

$$N ( z ) = ( {z}^{2} + 2 {a}_{1} z + {a}_{1}^{2} + {b}_{1}^{2} ) ( {z}^{2} + 2 {a}_{2} z + {a}_{2}^{2} + {b}_{2}^{2} ) ( {z}^{2} + 2 {a}_{3} z + {a}_{3}^{2} + {b}_{3}^{2} ) = ( {z}^{2} + 2 {a}_{1} z + 1 ) ( {z}^{2} + 2 {a}_{2} z + 1 ) ( {z}^{2} + 2 {a}_{3} z + 1 ) = {z}^{6} + ( 2 {a}_{1} + 2 {a}_{2} + 2 {a}_{3} ) {z}^{5} + ( 4 {a}_{1} {a}_{2} + 4 {a}_{1} {a}_{3} + 4 {a}_{2} {a}_{3} + 3 ) {z}^{4} + ( 8 {a}_{1} {a}_{2} {a}_{3} + 4 {a}_{1} + 4 {a}_{2} + 4 {a}_{3} ) {z}^{3} + ( 4 {a}_{1} {a}_{2} + 4 {a}_{1} {a}_{3} + 4 {a}_{2} {a}_{3} + 3 ) {z}^{2} + ( 2 {a}_{1} + 2 {a}_{2} + 2 {a}_{3} ) {z}^{1} + 1 \qquad ( 22 )$$

The polynomial of the denominator of the provisional FIR filter is the following Equation (23).

$$D ( z ) = {z}^{6} \qquad ( 23 )$$

In a case where the value of the instantaneous power is constantly 1, the active power is also 1. To do so, the FIR filter must have a gain of 1 for the direct current signal. The direct current gain of the provisional FIR filter is a value obtained by substituting z=1 into N(z)/D(z). First, the value N₀ of the numerator polynomial N(z) with respect to the direct current signal is calculated by the following Equation (24).

$${N}_{0} = 1 + ( 2 {a}_{1} + 2 {a}_{2} + 2 {a}_{3} ) + ( 4 {a}_{1} {a}_{2} + 4 {a}_{1} {a}_{3} + 4 {a}_{2} {a}_{3} + 3 ) + ( 8 {a}_{1} {a}_{2} {a}_{3} + 4 {a}_{1} + 4 {a}_{2} + 4 {a}_{3} ) + ( 4 {a}_{1} {a}_{2} + 4 {a}_{1} {a}_{3} + 4 {a}_{2} {a}_{3} + 3 ) + ( 2 {a}_{1} + 2 {a}_{2} + 2 {a}_{3} ) + 1 \qquad ( 24 )$$

The value D₀ of the denominator polynomial with respect to the direct current signal is expressed by the following Equation (25).

$${D}_{0} = 1 \qquad ( 25 )$$

The final FIR filter H(z) is obtained by correcting the provisional FIR filter by the following Equation (26) so that the direct current gain of the provisional FIR filter becomes 1.

$$H ( z ) = \frac{{D}_{0}}{{N}_{0}} ( 1 + ( 2 {a}_{1} + 2 {a}_{2} + 2 {a}_{3} ) {z}^{- 1} + ( 4 {a}_{1} {a}_{2} + 4 {a}_{1} {a}_{3} + 4 {a}_{2} {a}_{3} + 3 ) {z}^{- 2} + ( 8 {a}_{1} {a}_{2} {a}_{3} + 4 {a}_{1} + 4 {a}_{2} + 4 {a}_{3} ) {z}^{- 3} + ( 4 {a}_{1} {a}_{2} + 4 {a}_{1} {a}_{3} + 4 {a}_{2} {a}_{3} + 3 ) {z}^{- 4} + ( 2 {a}_{1} + 2 {a}_{2} + 2 {a}_{3} ) {z}^{- 5} + 1 ) \qquad ( 26 )$$

In the present embodiment, the case where the number of zero points is six has been described. This is an example, and the number of zero points is not limited to six. In a case where the number of zero points is odd, the odd number of zero points, for example, −1±j0 may be set on the real axis, and the present embodiment may be applied to the remaining even number of zero points. Further, in the present embodiment, the zero point is twice, four times, and six times the frequency of the alternating current, but the present invention is not limited thereto. In other embodiments, additional zero points may be added, such as eight times, ten times, or the like. Further, it may be added to three times, five times, seven times, or the like.

### (Actions and Effects)

In the adjustment power metering device 1 according to the third embodiment, the active power meter 14 includes an FIR filter 141 that cuts off a component corresponding to a vibration frequency of the alternating current instead of the FIR filter of the second embodiment. The vibration frequency of the alternating current is twice the value of the reference frequency of the alternating current. Specifically, the FIR filter 141 has a zero point on the unit circle of the complex plane at a position where the argument corresponds to one time the vibration frequency.

In this way, since the adjustment power metering device 1 can effectively remove the vibration of instantaneous power as in the second example embodiment, the supply and demand adjustment power of the power can be accurately metered.

Further, the FIR filter 141 may cut off a component corresponding to a frequency of an integral multiple of equal to or more than twice the vibration frequency. Specifically, the FIR filter 141 has a zero point on the unit circle of the complex plane at a position where the argument corresponds to an integral multiple of twice, three times, or more the vibration frequency.

In this way, for example, harmonic components that are twice, three times, or higher than the vibration frequency can be cut off in the same manner.

### Fourth Embodiment

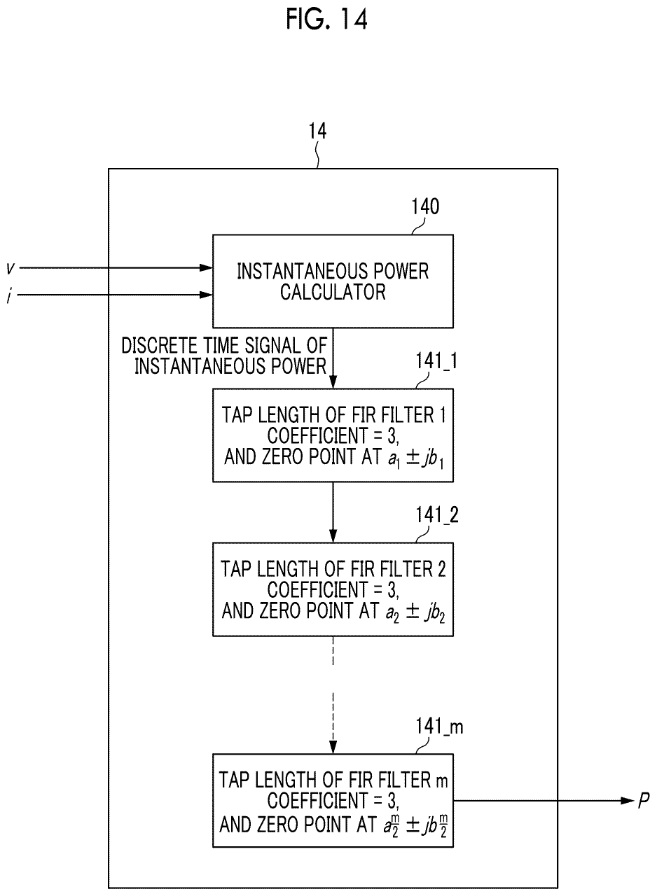

Next, a fourth embodiment will be described in detail with reference to FIG. 14. The same components as those of the above-described embodiment are denoted by the same reference numerals, and detailed description thereof will be omitted.

### (Functional Configuration of Active Power Meter)

FIG. 14 is a diagram showing a functional configuration of an active power meter according to a fourth embodiment.

In the fourth embodiment, as shown in FIG. 14, the active power meter 14 calculates the active power P by bonding a plurality of low-order FIR filters 141_1, 141_2, . . . , and 141_m in series. Each of the low-order FIR filters 141_1 to 141_m is characterized in that the tap length of the coefficient is 3, and each of the low-order FIR filters 141_1 to 141_m has one conjugate pair of zero points on the unit circle of the complex plane.

### (Processing of Active Power Meter)

In the present embodiment, the FIR filter H(z) is expressed as a product of low-order FIR filters 141_1 to 141_m having a tap length of 3 as in the following expression (27).

$$\begin{matrix}H ( z ) = \frac{{D}_{0}}{{N}_{0}} \frac{N ( z )}{D ( z )} \\ = \frac{{D}_{0}}{{N}_{0}} \frac{{z}^{2} + 2 {a}_{1} z + 1}{{z}^{2}} \frac{{z}^{2} + 2 {a}_{2} z + 1}{{z}^{2}} \frac{{z}^{2} + 2 {a}_{3} z + 1}{{z}^{2}} \\ = \frac{{D}_{0}}{{N}_{0}} ( 1 + 2 {a}_{1} {z}^{- 1} + {z}^{- 2} ) ( 1 + 2 {a}_{2} {z}^{- 1} + {z}^{- 2} ) ( 1 + 2 {a}_{3} {z}^{- 1} + {z}^{- 2} )\end{matrix} \qquad ( 27 )$$

For example, the low-order FIR filter 141_1 cuts off a response of one time the vibration frequency, the low-order FIR filter 141_2 cuts off a response of two times the vibration frequency, and the low-order FIR filter 141_m cuts off a response of m times the vibration frequency. In this way, by sequentially passing through the low-order FIR filters, it is possible to effectively remove the vibration of the instantaneous power at frequencies of 1 time, 2 times, . . . , and m times the vibration frequency.

### (Actions and Effects)

In the adjustment power metering device 1 according to the fourth embodiment, the active power meter 14 calculates the active power P by bonding a plurality of low-order FIR filters in series, each low-order FIR filter having a coefficient tap length of 3 and having a conjugate pair of zeros on a unit circle of a complex plane.

In the third embodiment, m FIR filter coefficients and 2m storage variables are required. On the other hand, in the fourth embodiment, the number of coefficients of the low-order FIR filter is m/2 (three in the example of the present embodiment), and the number of storage variables is m (six in the example of the present embodiment).

### Fifth Embodiment

In the second to fourth embodiments, an example in which the reference frequency (for example, 50 Hz) is used as the frequency f of the alternating current power has been described. In contrast, the fifth embodiment is characterized in that the coefficient of the FIR filter 141 is made variable based on the actual frequency f of the alternating current.

### (Processing of Active Power Meter)

In the present embodiment, the active power meter 14 removes the vibration component of the frequency 2f of the instantaneous power by constantly tuning the cutoff frequency of the FIR filter 141 to 2f.

Specifically, in the adjustment power metering device 1 according to the second embodiment, the weighting factor of the Hanning window is recalculated by substituting the value of f estimated by the frequency estimator 13 for f in the following Equation (28) instead of the Equation (14).

$$\{ \begin{matrix}h = \frac{1}{{c}_{H}} {\{ 0.5 - 0.5 cos {ω}_{k} \}}_{k = 0}^{m} \\ {ω}_{k} = min \{ \frac{2 π k f}{{f}_{s}} , 2 π \} , k ∈ \{ 0 , 1 , 2 , … , m \}\end{matrix} \qquad ( 28 )$$

According to Expression (28), when the frequency f is higher (for example, 50.1 Hz) than the reference frequency (for example, 50 Hz), the coefficient ok is adjusted so as not to exceed 2π (so as not to include data of the next cycle). In addition, when the frequency f is lower than the reference frequency (for example, 49.9 Hz), the tap length may be set to be longer than that of the second embodiment (for example, 34 or the like) so that samples for one cycle are not missed by an amount corresponding to the extension of the waveform. At this time, when the frequency f is 50 Hz and the number of acquired samples is 32, the values of the 33rd and 34th samples are set to 0. Thus, even in a case where the frequency f varies, necessary samples can be appropriately acquired.

In the adjustment power metering device 1 according to the third and fourth embodiments, the zero point is determined by substituting the value of f estimated by the frequency estimator 13 for f in the following Equation (29) instead of the Equation (21).

$$\{ {a}_{1} + j {b}_{1} , {a}_{2} + j {b}_{2} , {a}_{3} + j {b}_{3} \} = \{ {e}^{\pm j \frac{2 π 2 f}{{f}_{s}}} , {e}^{\pm j \frac{2 π 4 f}{{f}_{s}}} , {e}^{\pm j \frac{2 π 6 f}{{f}_{s}}} \} \qquad ( 29 )$$

### (Actions and Effects)

In the adjustment power metering device 1 according to the fifth embodiment, the active power meter 14 changes the coefficient of the FIR filter 141 based on the frequency estimated by the frequency estimator 13.

In this way, the adjustment power metering device 1 can measure the active power more accurately by changing the coefficient of the FIR filter 141 in accordance with the frequency f that fluctuates from moment to moment.

### Modification Example 1

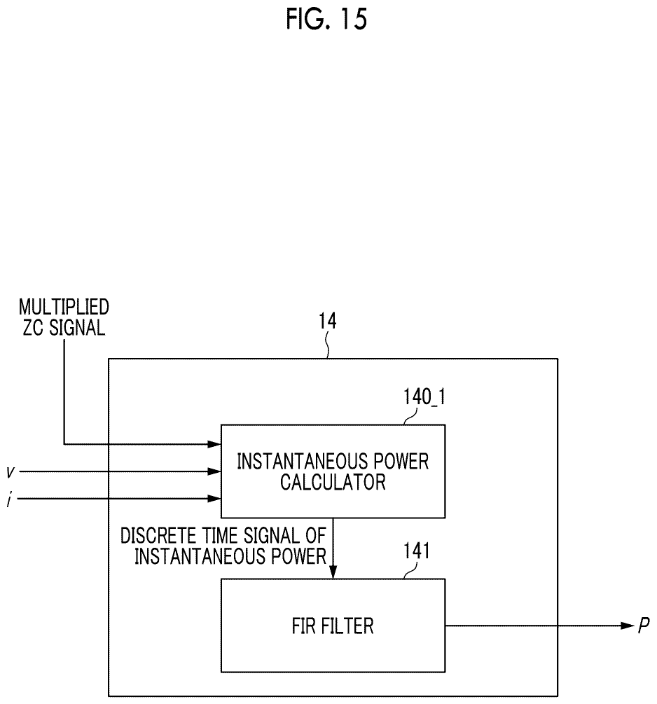

FIG. 15 is a diagram showing a functional configuration of an active power meter according to a Modification Example of the fifth embodiment.

In the Modification Example 1, the calculation of the FIR filter 141 is synchronized with the cycle of the alternating current, thereby eliminating the need to recalculate the weighting factor of the Hanning window. This will be described with reference to FIG. 15. The instantaneous power calculator 140_1 of the Modification Example 1 receives the multiplied ZC signal shown in FIG. 7, calculates a discrete time signal of the instantaneous power p from the voltage v and the current i based on the multiplied ZC signal, and outputs the discrete time signal. The FIR filter 141 is the same as that of the fifth embodiment. The FIR filter 141 receives the discrete time signal of the instantaneous power p and calculates the active power P.

### Sixth Embodiment

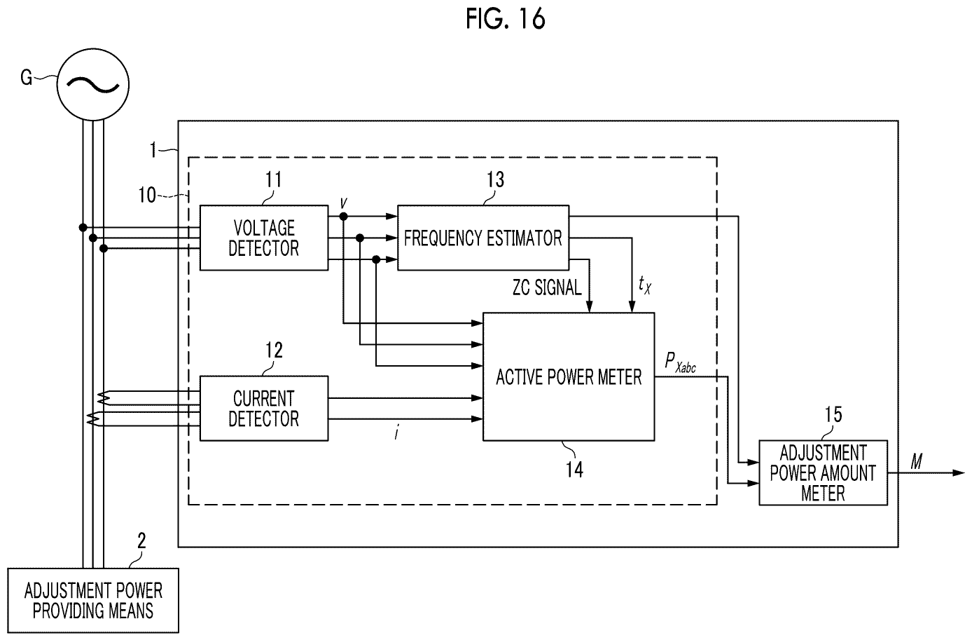

Next, a sixth embodiment will be described in detail with reference to FIG. 16. The same components as those of the above-described embodiment are denoted by the same reference numerals, and detailed description thereof will be omitted.

### (Functional Configuration of Adjustment Power Metering Device)

FIG. 16 is a diagram showing a functional configuration of an adjustment power metering device according to a sixth embodiment.

As shown in FIG. 16, in the alternating current power system G according to the sixth embodiment, three-phase alternating current is used.

The voltage detector 11 measures and outputs a phase voltage of each phase of the three-phase alternating current.

The current detector 12 detects and outputs currents of two phases of the three-phase alternating current.

The frequency estimator 13 estimates a frequency f of at least one phase of the three-phase alternating current.

The active power meter 14 estimates the active power P of the entire three phases from the moving average value of the sum of the instantaneous powers of the respective phases of the three-phase alternating current.

The adjustment power amount meter 15 calculates the supply and demand adjustment power M of the power based on the temporal difference ΔP of the active power P in all three phases and the temporal difference Δf of the frequency f.

### (Processing of Adjustment Power Metering Device)

In the case of a single-phase alternating current, even in a case where the current and voltage of the alternating current are constant, the instantaneous active power cyclically fluctuates at a frequency twice that of the alternating current. Therefore, in the calculation of the active power, the width of the time window of the moving average has to be an integral multiple of the cycle of the alternating current. For example, in the case of an alternating current of 50 Hz, it is necessary to set the width of the window of the moving average to an integral multiple of 2 ms in order to measure the active power. Therefore, assuming that the value of the active power is calculated at a certain time, it is necessary to wait for 2 ms until the value of the active power can be calculated with the newly measured instantaneous power. When the alternating current is vertically symmetrical, it may be 1 ms which is a half cycle of the alternating current.

However, in a case where the metering target is a three-phase alternating current and the current and the voltage are constant, the sum of the three-phase instantaneous active power is temporally constant. Therefore, the length of the window of the moving average can be determined independently of the cycle of the alternating current as in the case of the single-phase active power.

In the present embodiment, the voltage detector 11 meters the phase voltage v of each phase of the three-phase alternating current. The current detector 12 detects currents i of two of the three phases. When each of the three phases is represented by a symbol {a, b, c}, it is sufficient to calculate the sum of two powers from the Brondel's theorem as the instantaneous power p_{abc} that is the sum of the three phases as in Equation (30).

$$\begin{matrix}{p}_{a b c} = {v}_{a} {i}_{a} + {v}_{b} {i}_{b} + {v}_{c} {i}_{c} \\ = {v}_{a} {i}_{a} + {v}_{b} {i}_{b} + {v}_{c} ( - {i}_{a} - {i}_{c} ) \\ = ( {v}_{a} - {v}_{c} ) {i}_{a} + ( {v}_{b} - {v}_{c} ) {i}_{b}\end{matrix} \qquad ( 30 )$$

As described above, since the sum of the instantaneous active powers of the three phases is temporally constant, the instantaneous power p_{abc} obtained by summing the instantaneous active powers of the three phases represents the active power. Therefore, the value of the three-phase active power can be determined by the frequency of calculation of the instantaneous active power.

On the other hand, the frequency estimator 13 calculates the frequency f from the time of zero crossing of the voltage. There are two zero crossings per cycle for one phase. In the three-phase, since there are six zero crossings per cycle, the value of the frequency is known at a frequency of six times per cycle. When the time of the zero cross is denoted by t_{X} without distinguishing the phase and without distinguishing whether the zero cross is from positive to negative or from negative to positive, the frequency can be calculated by a method such as Equation (31), Equation (32), or Equation (33).

$$f = \frac{1}{6} \frac{1}{Δ {t}_{X}} \qquad ( 31 )$$

$$f = \frac{1}{2} \frac{1}{{Δ}_{3} {t}_{X}} \qquad ( 32 )$$

$$f = \frac{1}{{Δ}_{6} {t}_{X}} \qquad ( 33 )$$

Equation (31) calculates the frequency from the time difference of the previous zero crossing. Equation (32) calculates the frequency from the time difference of the zero cross three times before. This distinguishes the phases and calculates the frequency from the time difference from the zero crossing of the same phase half cycle before. In the Equation (33), the phase is distinguished, and the frequency is calculated from the time difference from the zero cross of the same phase one cycle before. The calculation of the frequency may be performed by various methods other than these Equations. When generalized, it is expressed by Equation (34) using a weighting coefficient β. t_{X,0} represents the time of the most recent zero crossing. t_{X,-1} is the time of the previous zero crossing. For example, when β={6, −6, 0, 0, 0, 0, 0, 0, . . . }, this is the same as Equation (22).

$$f = \frac{1}{{\sum }_{i = 1}^{∞} {β}_{i} {t}_{X , 1 - i}} \qquad ( 34 )$$

The frequency estimator 13 outputs the ZC signal indicating the occurrence of the zero cross, the time t_{X} of the zero cross, and the frequency f.

Based on the output signal of the frequency estimator 13, the active power meter 14 calculates the average active power in the time interval of the frequency calculation in synchronization with the frequency calculation. In a case where the frequency is calculated by Equation (31), the calculation of the average active power is represented by Equation (35).

$${P}_{X a b c} = \frac{1}{Δ {t}_{X}} {\int }_{{t}_{X , - 1}}^{{t}_{X , 0}} {p}_{a b c} d t \qquad ( 35 )$$

The adjustment power amount meter 15 meters the adjustment power amount by the following Equation (36), similarly to the Equation (11).

$${M}_{{t}_{X}} = {\sum }_{τ = 1 , 2 , 3 , … , {t}_{X}} - sgn ( Δ {f}_{τ} ) \cdot Δ {P}_{X a b c} \cdot Δ {t}_{{x}_{τ}} \qquad ( 36 )$$

### (Actions and Effects)

The adjustment power metering device 1 according to the sixth embodiment includes a frequency estimator 13 that estimates the frequency of the alternating current of at least one phase of the three-phase alternating current, an active power meter 14 that meters the active power of all three phases from the moving average value of the sum of the instantaneous power of each phase of the three-phase alternating current, and an adjustment power amount meter 15 that calculates the supply and demand adjustment power of the power based on the temporal difference of the active power and the temporal difference of the frequency.

In this way, unlike the first embodiment, the adjustment power metering device 1 can determine the length of the window of the moving average regardless of the cycle of the alternating current.

### Seventh Embodiment

In the seventh exemplary embodiment, in the adjustment power metering device 1, the adjustment power amount meter 15 may calculate the supply and demand adjustment power of the power based on the temporal difference of the frequency of the alternating current, the temporal second-order difference of the frequency, the weighted sum of the deviations of the frequency from the reference frequency, and the temporal difference of the active power. Any one of the first to sixth embodiments described above is applied to the other configurations.

In the description of the related art, the governor free operation of Equation (2) has been described as a specific example of the supply and demand adjustment of the power system. Since the time difference of the frequency and the time difference of the active power are in a proportional relationship, the governor free operation can be realized by a proportional controller. A PID controller is generally known as a proportional controller. In PID, P represents proportion, I represents integration, and D represents differentiation. When the PID controller is applied to supply and demand adjustment of the power, the output thereof is expressed by Equation (37) as a weighted sum of outputs of a proportional controller, an integral controller, and a differentiation controller. Δ2 means a temporal second-order difference.

$$Δ {f}_{PID} = α Δ f + β ( f - 50 Hz ) Δ f + γ \frac{{Δ}^{2} f}{Δ t} \qquad ( 37 )$$

By applying ΔP given by the Equation (37) to the Equation (3) of the adjustment power, the following Equation (38) is obtained as the supply and demand adjustment power for the PID controller.

$${M}_{t} = {\sum }_{τ = 1}^{t} - sgn ( α Δ {f}_{τ} + β ( {f}_{τ} - 50 Hz ) Δ t + γ \frac{{Δ}^{2} {f}_{τ}}{Δ t} ) \cdot Δ {P}_{τ} \cdot Δ t \qquad ( 38 )$$

α, β, and γ are load coefficients for proportional control, integral control, and differentiation control, respectively. In addition to proportion, integration, and differentiation, a transfer function may be used.

In this way, the adjustment power metering device 1 can accurately evaluate whether the direction in which the response to the frequency fluctuation should be made and the direction of the change in the actual power supply and demand match each other based on the various parameters.

### Eighth Embodiment

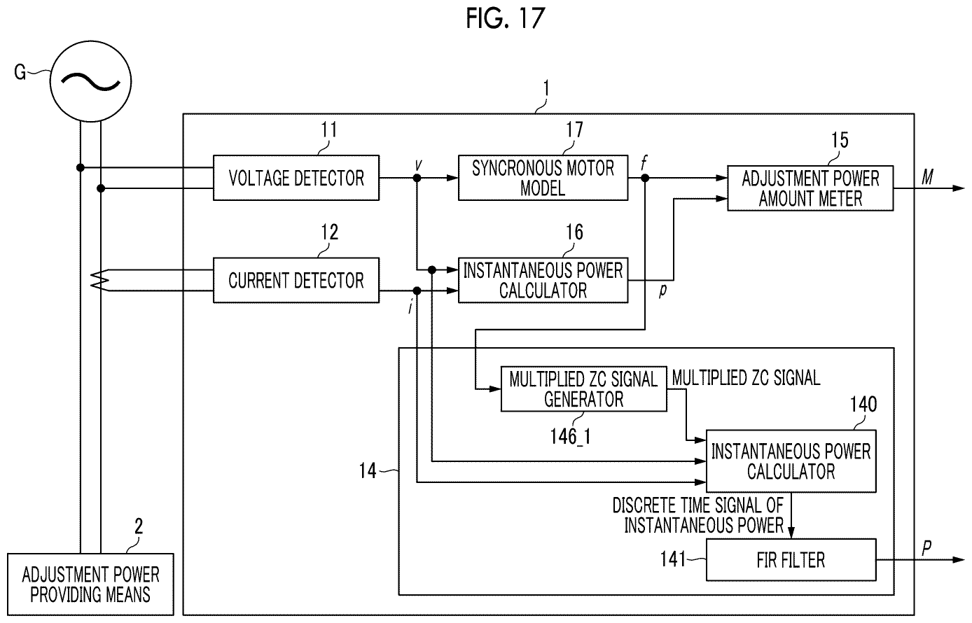

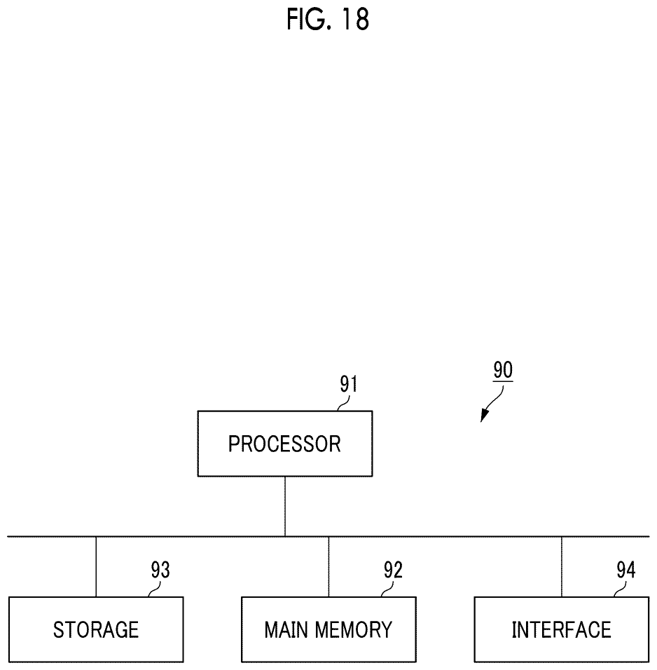

Next, an eighth embodiment will be described in detail with reference to FIG. 17. The same components as those of the above-described embodiment are denoted by the same reference numerals, and detailed description thereof will be omitted.

In the related art, as described above, the active power P is calculated from the moving average of the instantaneous power p for n cycles (for example, 10 cycles) of the alternating current. The temporal length of the n cycles fluctuates with the frequency of the alternating current, so that ripples remain in the active power. In order to remove the influence of the ripple more reliably, it is conceivable to increase the cycle of the moving average to, for example, 50 cycles or 100 cycles. However, in this case, the moving average value is delayed in time, and the fast response component of one second or less cannot be metered.

In consideration of such a problem, in each of the above-described embodiments, in order to reduce the ripple, the technique of calculating the active power for each cycle of the alternating current and metering the adjustment power based on the active power has been described. On the other hand, in the present embodiment, a technique of metering the adjustment power based on the instantaneous power of the alternating current and the frequency of the alternating current calculated by the synchronous motor model 17 without calculating the active power will be described.

FIG. 17 is a diagram showing a functional configuration of an adjustment power metering device according to an eighth embodiment.

As shown in FIG. 17, the adjustment power metering device 1 according to the present embodiment includes an instantaneous power calculator 16 and a synchronous motor model 17.

The instantaneous power calculator 16 calculates the instantaneous power pₜ of the alternating current exchanged between the alternating current power system G and the adjustment power providing means 2 from the instantaneous voltage vₜ and the instantaneous current it metered by the voltage detector 11 and the current detector 12.

The synchronous motor model 17 is a numerical model that receives the instantaneous voltage vₜ as an input, calculates the rotation speed of the synchronous motor included in the adjustment power providing means 2, and outputs the frequency fₜ of the alternating current. Conventionally, the rotation speed of the synchronous motor is obtained by detecting the zero cross, so that the rotation speed can be metered only intermittently (once or twice in one cycle). However, in the present embodiment, the rotation speed of the synchronous motor can be substantially continuously calculated at the frequency of inputting the instantaneous voltage vₜ, and the rotation speed can be con verted into a frequency. Therefore, the frequency of the alternating current can be substantially continuously metered by using the synchronous motor model 17. The term “substantially continuously” means that the signal is a temporally dense discrete signal, for example, 32 times or more in one cycle, and is continuous in contrast to once or twice in one cycle.

Further, the adjustment power amount meter 15 according to the present embodiment calculates the adjustment power Mt at the time t by the following Equation (39) instead of the above-described Equation (3).

$${ℳ}_{t} = {\sum }_{τ = 1}^{t} - sgn ( Δ {f}_{τ} ) \cdot Δ {p}_{τ} \cdot Δ t \qquad ( 39 )$$

In this way, the adjustment power metering device 1 can improve the responsiveness of metering the adjustment power.

In the present embodiment, an example in which the synchronous motor mode 1 17 receives the instantaneous voltage vₜ as an input and outputs the frequency fₜ of the alternating current of the synchronous motor has been described. However, in another embodiment, the synchronous motor model 17 may output the rotation speed of the synchronous motor, and the adjustment power amount meter 15 may calculate the frequency fₜ of the alternating current from the rotation speed of the synchronous motor.

Further, the adjustment power metering device 1 according to the present embodiment may function as the active power metering device 10 having the active power meter 14. In this case, the ZC signal and the multiplied ZC signal may be generated from the frequency fₜ of the alternating current output by the synchronous motor. The frequency represents the phase velocity, and when it is integrated over time, the angle of the phase is obtained. For example, in a case where the phase angle when the voltage v crosses zero is defined as 0 degree, the phase angle of the voltage v can be obtained. In a case where a signal is transmitted every time the phase angle of the voltage v crosses 0 degree, the ZC signal can be substituted. Further, for example, in a case where the ZC signal is transmitted when the phase angle exceeds 0 degrees, 90 degrees, 180 degrees, or 270 degrees, the multiplied ZC signal can be substituted. The multiplied ZC signal generator 146_1 of FIG. 17 receives the frequency of the alternating current fₜ, performs the above-described processing, and outputs a multiplied ZC signal. When the multiplied ZC signal is input to the instantaneous power calculator 140, ripples are removed by the FIR filter 141, and the active power P can be calculated. When the synchronous motor model 17 is used, the multiplication rate of the multiplied ZC signal can be freely determined. For example, since it is possible to transmit the multiplied ZC signal every one degree of the motor rotation angle, the responsiveness of the metering of the active power can be improved.

### <Computer Configuration>

FIG. 18 is a schematic block diagram showing a configuration of a computer according to at least one exemplary embodiment.

As shown in FIG. 18, a computer 90 includes a processor 91, a main memory 92, a storage 93, and an interface 94.

The adjustment power metering device 1 described above is mounted on the computer 90. The operation of each processing unit described above is stored in the storage 93 in the form of a program. The processor 91 reads the program from the storage 93, develops the program in the main memory 92, and executes the above-described processing according to the program. In addition, the processor 91 secures a storage area corresponding to each storage unit described above in the main memory 92 according to the program.

The program may be for realizing a part of the functions to be exhibited by the computer 90. For example, the program may exhibit a function in combination with another program already stored in a storage or in combination with another program installed in another device. In another embodiment, the computer may include a custom large scale integrated (LSI) circuit such as a programmable logic device (PLD) in addition to or instead of the above configuration. Examples of the PLD include a programmable array logic (PAL), a generic array logic (GAL), a complex programmable logic device (CPLD), and a field programmable gate array (FPGA). In this case, some or all of the functions implemented by the processor may be implemented by the integrated circuit.

Examples of the storage 93 include a hard disk drive (HDD), a solid state drive (SSD), a magnetic disk, a magneto-optical disk, a compact disc read only memory (CD-ROM), a digital versatile disc read only memory (DVD-ROM), and a semiconductor memory. The storage 93 may be an internal medium directly connected to a bus of the computer 90, or may be an external medium connected to the computer 90 via the interface 94 or a communication line. In addition, in a case where the program is distributed to the computer 90 through a communication line, the computer 90 that has received the distribution may develop the program in the main memory 92 and execute the above-described processing. In at least one embodiment, the storage 93 is a non-transitory tangible storage medium.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

### <Additional Notes>

The embodiments described above are understood as follows, for example.

(1) According to a first aspect, an active power metering device 10 includes: a frequency estimator 13 configure to estimate a cycle and a frequency of an alternating current transmitted to or received from a power system by a target device 2 based on a time series of a voltage of the alternating current; and an active power meter 14 configured to calculate a moving average value of instantaneous power in a plurality of cycles of the alternating current for each cycle of the alternating current, and meter active power exchanged by the target device 2 in one cycle of the alternating current from a difference between the calculated moving average value and a previously calculated moving average value.

In this way, the active power metering device 10 can meter the active power at short intervals of one cycle. For example, when the reference frequency of the alternating current is 50 Hz, one cycle is 20 ms. Therefore, the active power metering device 10 can significantly improve the responsiveness of metering as compared with the related art in which metering can be performed only every 10 cycles (200 ms).

(2) According to the second aspect, the active power metering device 10 includes: a frequency estimator 13 configure to estimate a cycle and a frequency of an alternating current based on a time series of a voltage of the alternating current transmitted to or received from a power system by a target device 2; and an active power meter 14 configured to meter active power exchanged by the target device 2 from an integrated value of instantaneous power in one cycle of the alternating current.

In this way, the active power metering device 10 can accurately calculate the active power per cycle of the alternating current.

(3) According to a third aspect, an active power metering device 10 includes: a frequency estimator 13 configured to estimate a cycle and a frequency of an alternating current transmitted to or received from a power system by a target device 2 based on a time series of a voltage of the alternating current; and an active power meter 14 including an instantaneous power calculator 140 configured to calculate instantaneous power of the alternating current at a frequency that is an integral multiple of the frequency of the alternating current, and output a discrete time signal of the instantaneous power in one cycle of the alternating current, and a finite impulse response filter 141 having a Hanning window whose tap length matches a calculation frequency of the instantaneous power as a coefficient, the active power meter being configured to filter a discrete signal of the instantaneous power with the finite impulse response filter 141 and meter active power exchanged by the target device 2.

In this way, the active power meter 14 can complete the calculation of the active power only for one cycle, so that the responsiveness of the active power metering can be further improved.

(4) According to a fourth aspect, an active power metering device 10 includes: a frequency estimator 13 configured to estimate a cycle and a frequency of an alternating current based on a time series of a voltage of the alternating current transmitted to or received from a power system by a target device 2; an instantaneous power calculator 140 configured to calculate an instantaneous power of the alternating current at a frequency that is an integral multiple of the frequency of the alternating current, and output a discrete time signal of the instantaneous power in one cycle of the alternating current; and an active power meter 14 configured to filter a discrete signal of the instantaneous power with a finite impulse response filter 141 that cuts off a component corresponding to a vibration frequency of the alternating current, and meter active power exchanged by the target device 2.

In this way, the active power metering device 10 can effectively remove the vibration of the instantaneous power, and thus can accurately meter the active power.

(5) According to a fifth aspect, in the active power metering device 10 according to the fourth aspect, the finite impulse response filter 141 has a zero point on a unit circle of a complex plane at a position where an argument corresponds to an integral multiple of the vibration frequency, the integral multiple being equal to or more than one time or two times the vibration frequency.

In this way, for example, harmonic components that are twice, three times, or the like the vibration frequency can be cut off in the same manner.

(6) According to a sixth aspect, in the active power metering device 10 according to the fourth aspect, the finite impulse response filter 141 is configured by coupling a plurality of low-order finite impulse response filters in series, each of the low-order finite impulse response filters having a coefficient tap length of 3 and a conjugate pair of zero points on a unit circle of a complex plane.

In this way, the number of coefficients of the low-order FIR filter is m/2 (three in the example of the embodiment described above), and the number of storage variables is m (six in the example of the embodiment described above).

(7) According to a seventh aspect, an active power metering device 10 includes: a frequency estimator 13 configured to estimate a frequency of an alternating current of at least one phase of a three-phase alternating current transmitted to or received from a power system by a target device 2 based on a time series of a voltage of the three-phase alternating current; and an active power meter 14 configured to meter active power of all three phases of the target device 2 from a moving average value of a sum of instantaneous power of each phase of the three-phase alternating current.

In this way, the active power metering device 10 can determine the length of the window of the moving average of the active power regardless of the cycle of the alternating current.

(8) According to an eighth aspect, in the active power metering device 10 according to any one of the third to sixth aspects, the active power meter 14 changes a coefficient of the finite impulse response filter 141 based on the frequency estimated by the frequency estimator 13.

In this way, the active power metering device 10 can meter the active power more accurately by changing the coefficient of the FIR filter 141 in accordance with the frequency f that fluctuates from moment to moment.

(9) According to the ninth aspect, the active power metering device 10 includes: a synchronous motor model 17 configured to receive, as an input, an instantaneous voltage v of an alternating current transmitted to or received from a power system by a target device 2, calculate a rotation speed of a synchronous motor included in the target device 2, and output a frequency f of the alternating current; and an active power meter 14 configured to meter active power P exchanged by the target device 2 in one cycle of the alternating current based on an instantaneous current i of the alternating current, the instantaneous voltage v, and the frequency f output from the synchronous motor model 17.

In this way, the active power metering device 10 can reliably remove the influence of the ripple and improve the responsiveness of the metering.

(10) According to a tenth aspect, an adjustment power metering device 1 includes: the active power metering device 10 according to any one of the above described aspects; and an adjustment power amount meter 15 configured to calculate a supply and demand adjustment power of the target device 2 based on a temporal difference of the active power and a temporal difference of the frequency.

In this way, the adjustment power metering device 1 can obtain the difference for each cycle of the alternating current with respect to the active power P and the frequency f, and calculate the supply and demand adjustment power M for each cycle from the difference. Therefore, it is possible to improve the responsiveness of the adjustment power metering. Accordingly, the adjustment power metering device 1 can measure a fast adjustment power such as an inertial force.

(11) According to an eleventh aspect, in the adjustment power metering device 1 according to the tenth aspect, the adjustment power amount meter 15 calculates the supply and demand adjustment power based on the temporal difference of the frequency of the alternating current, a temporal second-order difference of the frequency, a weighted sum of deviations of the frequency from a reference frequency, and the temporal difference of the active power.

In this way, the adjustment power metering device 1 can accurately evaluate whether the direction in which the response to the frequency fluctuation should be made and the direction of the change in the actual power supply and demand match each other based on the various parameters.

(12) According to a twelfth aspect, a metering method includes: a step of estimating a cycle and a frequency of an alternating current based on a time series of a voltage of the alternating current transmitted to or received from a power system by a target device 2; a step of calculating instantaneous power of the alternating current at a frequency that is an integral multiple of the frequency of the alternating current, and outputting a discrete time signal of the instantaneous power in one cycle of the alternating current; and a step of metering active power exchanged by the target device 2 by filtering a discrete signal of the instantaneous power with a finite impulse response filter 141 having a Hanning window whose tap length matches a calculation frequency of the instantaneous power as a coefficient.

(13) According to a thirteenth aspect, a program causes the active power metering device 10 to execute: a step of estimating a cycle and a frequency of an alternating current based on a time series of a voltage of the alternating current transmitted to or received from a power system by a target device 2; a step of calculating instantaneous power of the alternating current at a frequency that is an integral multiple of the frequency of the alternating current, and outputting a discrete time signal of the instantaneous power in one cycle of the alternating current; and a step of metering active power exchanged by the target device 2 by filtering a discrete signal of the instantaneous power with a finite impulse response filter 141 having a Hanning window whose tap length matches a calculation frequency of the instantaneous power as a coefficient.

### INDUSTRIAL APPLICABILITY

According to the above aspects, it is possible to improve the responsiveness of power measurement.

### REFERENCE SIGNS LIST

1: adjustment power metering device
2: adjustment power providing means
10: active power metering device
11: voltage detector
12: current detector
13: frequency estimator
130: timer
131: zero crossing detector (ZC detector)
132: sampler
133: frequency calculation unit
14: active power meter
140: instantaneous power calculator
141: finite impulse response filter (FIR filter)
141,141_1,141_2,141_m: low-order FIR filter
142: instantaneous power integrator
143: sampler
144: active power calculation unit
15: adjustment power amount meter
16: instantaneous power calculator
17: synchronous motor model

1. An active power metering device comprising:
a frequency estimator configured to estimate a cycle and a frequency of an alternating current transmitted to or received from a power system by a target device based on a time series of a voltage of the alternating current; and
an active power meter configured to calculate a moving average value of instantaneous power in a plurality of cycles of the alternating current for each cycle of the alternating current, and meter active power exchanged by the target device in one cycle of the alternating current from a difference between the calculated moving average value and a previously calculated moving average value.

2. An active power metering device comprising:
a frequency estimator configured to estimate a cycle and a frequency of an alternating current transmitted to or received from a power system by a target device based on a time series of a voltage of the alternating current; and
an active power meter configured to meter active power exchanged by the target device from an integrated value of instantaneous power in one cycle of the alternating current.

3. An active power metering device comprising:
a frequency estimator configured to estimate a cycle and a frequency of an alternating current transmitted to or received from a power system by a target device based on a time series of a voltage of the alternating current; and
an active power meter including an instantaneous power calculator configured to calculate instantaneous power of the alternating current at a frequency that is an integral multiple of the frequency of the alternating current, and output a discrete time signal of the instantaneous power in one cycle of the alternating current, and a finite impulse response filter having a Hanning window whose tap length matches a calculation frequency of the instantaneous power as a coefficient, the active power meter being configured to filter a discrete signal of the instantaneous power with the finite impulse response filter and meter active power exchanged by the target device.

4. An active power metering device comprising:
a frequency estimator configured to estimate a cycle and a frequency of an alternating current based on a time series of a voltage of the alternating current transmitted to or received from a power system by a target device;
an instantaneous power calculator configured to calculate an instantaneous power of the alternating current at a frequency that is an integral multiple of the frequency of the alternating current, and output a discrete time signal of the instantaneous power in one cycle of the alternating current; and
an active power meter configured to filter a discrete signal of the instantaneous power with a finite impulse response filter that cuts off a component corresponding to a vibration frequency of the alternating current, and meter active power exchanged by the target device.

5. The active power metering device according to claim 4, wherein the finite impulse response filter has a zero point on a unit circle of a complex plane at a position where an argument corresponds to an integral multiple of the vibration frequency, the integral multiple being equal to or more than one time or two times the vibration frequency.

6. The active power metering device according to claim 4, wherein the finite impulse response filter is configured by coupling a plurality of low-order finite impulse response filters in series, each of the low-order finite impulse response filters having a coefficient tap length of 3 and a conjugate pair of zero points on a unit circle of a complex plane.

7. An active power metering device comprising:
a frequency estimator configured to estimate a frequency of an alternating current of at least one phase of a three-phase alternating current transmitted to or received from a power system by a target device based on a time series of a voltage of the three-phase alternating current; and
an active power meter configured to meter active power of all three phases of the target device from a moving average value of a sum of instantaneous power of each phase of the three-phase alternating current.

8. The active power metering device according to claim 3, wherein the active power meter changes a coefficient of the finite impulse response filter based on the frequency estimated by the frequency estimator.

9. An active power metering device comprising:
a synchronous motor model configured to receive, as an input, an instantaneous voltage of an alternating current transmitted to or received from a power system by a target device, calculate a rotation speed of a synchronous motor included in the target device, and output a frequency of the alternating current; and
an active power meter configured to meter active power exchanged by the target device in one cycle of the alternating current based on an instantaneous current of the alternating current, the instantaneous voltage, and the frequency output from the synchronous motor model.

10. An adjustment power metering device comprising:
the active power metering device according to claim 1; and
an adjustment power amount meter configured to calculate a supply and demand adjustment power of the target device based on a temporal difference of the active power and a temporal difference of the frequency.

11. The adjustment power metering device according to claim 10, wherein the adjustment power amount meter calculates the supply and demand adjustment power based on the temporal difference of the frequency of the alternating current, a temporal second-order difference of the frequency, a weighted sum of deviations of the frequency from a reference frequency, and the temporal difference of the active power.

12. A metering method comprising:
a step of estimating a cycle and a frequency of an alternating current based on a time series of a voltage of the alternating current transmitted to or received from a power system by a target device;
a step of calculating instantaneous power of the alternating current at a frequency that is an integral multiple of the frequency of the alternating current, and outputting a discrete time signal of the instantaneous power in one cycle of the alternating current; and
a step of metering active power exchanged by the target device by filtering a discrete signal of the instantaneous power with a finite impulse response filter having a Hanning window whose tap length matches a calculation frequency of the instantaneous power as a coefficient.

13. A non-transitory computer readable media storing instructions causing an active power metering device to execute:
a step of estimating a cycle and a frequency of an alternating current based on a time series of a voltage of the alternating current transmitted to or received from a power system by a target device;
a step of calculating instantaneous power of the alternating current at a frequency that is an integral multiple of the frequency of the alternating current, and outputting a discrete time signal of the instantaneous power in one cycle of the alternating current; and
a step of metering active power exchanged by the target device by filtering a discrete signal of the instantaneous power with a finite impulse response filter having a Hanning window whose tap length matches a calculation frequency of the instantaneous power as a coefficient.
